(19) United States
(12) Patent Application Publication
(10) Pub. No.: US 2013/0299814 A1
(43) Pub. Date: Nov. 14, 2013

(54) ORGANIC COMPOUND, ORGANIC LIGHT-EMITTING DEVICE, AND IMAGE DISPLAY APPARATUS

(71) Applicants: Hirokazu Miyashita, Tokyo (JP); Jun Kamatani, Tokyo (JP); Akihito Saitoh, Gotemba-shi (JP)

(72) Inventors: Hirokazu Miyashita, Tokyo (JP); Jun Kamatani, Tokyo (JP); Akihito Saitoh, Gotemba-shi (JP)

(73) Assignee: CANON KABUSHIKI KAISHA, Tokyo (JP)

(21) Appl. No.: 13/982,217

(22) PCT Filed: Dec. 9, 2011
(86) PCT No.: PCT/JP2011/079262

§ 371 Date: Jul. 26, 2013

(30) Foreign Application Priority Data
Jan. 31, 2011 (JP) 2011-018366

(51) Int. Cl. H01L 51/00

(52) U.S. Cl. CPC H01L 51/0058
USPC 257/40; 546/255; 564/426; 558/411; 556/489; 568/632; 570/129; 585/27

(57) ABSTRACT

The present invention provides an organic compound of which basic skeleton emits light in a yellow range by itself with high luminous efficiency. The organic compound is represented by claim 1.

### TECHNICAL FIELD

The present invention relates to an organic compound and an organic light-emitting device and an image display apparatus using the compound.

### BACKGROUND ART

An organic light-emitting device (organic electroluminescent device: organic EL device) is an electronic element including a pair of electrodes composed of an anode and a cathode and an organic compound layer disposed between these electrodes. Electrons and holes are injected from the pair of electrodes into the organic compound layer to generate excitons of the organic light-emitting compound in the organic compound layer, and the organic light-emitting device emits light when the excitons return to the ground state.

The organic light-emitting devices have remarkably progressed recently and are characterized by low driving voltages, various emission wavelengths, rapid response, and reductions in size and weight of light-emitting devices.

In order to provide high-performance organic light-emitting devices, creation of compounds having excellent light-emitting characteristics is important. Accordingly, light-emitting organic compounds have been actively being created.

As compounds that have been created until now, for example, compounds having Compound 1-A (naphthofluoranthene) as basic skeletons are proposed in PTL 1. The color of light emitted by Compound 1-A (naphthofluoranthene) itself is blue.

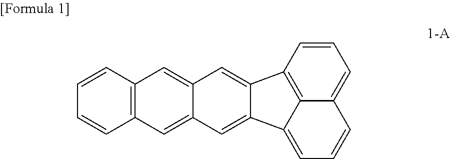 [SMILES: c1ccc2cc3cc4c(cc3cc2c1)-c1cccc2cccc-4c12]

As another example, compounds having Compound 1-B shown below as basic skeletons are proposed in PTL 2.

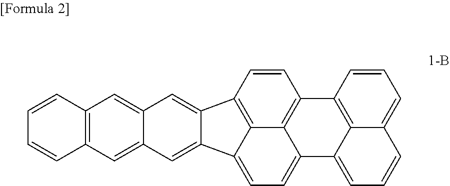 [SMILES: c1ccc2cc3cc4c(cc3cc2c1)-c1ccc2c3cccc5cccc(c6ccc-4c1c26)c53]

### CITATION LIST

### Patent Literature

PTL 1 Japanese Patent Laid-Open No. Hei 10-294177
PTL 2 Japanese Patent Laid-Open No. 2003-272866

### SUMMARY OF INVENTION

Unfortunately, in the compounds proposed in PTL 2, the intermolecular interaction is strong due to the high flatness of the molecule. Therefore, in the case of using the compounds as constituent materials, for example, light-emitting materials, of organic light-emitting devices, a reduction in luminous efficiency due to concentration quenching is caused when they are used in high concentrations. In addition, no compounds having Compound 1-A or Compound 1-B as basic skeletons have been reported to emit light in a yellow range with excellent luminous efficiency.

### Solution to Problem

The present invention has been made for solving the above-described problems and provides an organic compound of which basic skeleton emits light in a yellow range by itself with high luminous efficiency.

The organic compound according to the present invention is a compound represented by the following Formula (1).

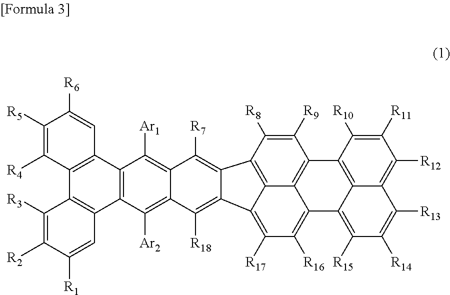

In Formula (1), R₁ to R₁₈ each independently represent a substituent selected from hydrogen atoms, halogen atoms, substituted or unsubstituted alkyl groups, substituted or unsubstituted alkoxy groups, substituted or unsubstituted amino groups, substituted or unsubstituted aryl groups, and substituted or unsubstituted heterocyclic groups; and Ar₁ and Ar₂ each represent a substituted or unsubstituted aryl group.

In the organic compound according to the present invention, the basic skeleton itself is excellent in inhibition of molecular packing. Therefore, the change in emission wavelength is small even if the compound is used in a high concentration. According to the present invention, an organic compound of which basic skeleton emits light in a yellow range by itself with high luminous efficiency is provided.

### BRIEF DESCRIPTION OF DRAWINGS

FIG. 1A shows PL spectra of Sample A (toluene solution).

FIG. 1B shows PL spectra of Sample B (doped film).

FIG. 2 is a schematic cross-sectional view illustrating an example of a display apparatus having organic light-emitting devices according to an embodiment of the present invention and TFT devices as an example of switching elements electrically connected to the organic light-emitting devices.

### DESCRIPTION OF EMBODIMENT

The organic compound according to the present invention is represented by the following Formula (1).

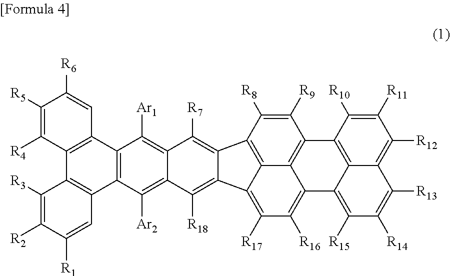

In Formula (1), R₁ to R₁₈ each independently represent a substituent selected from hydrogen atoms, halogen atoms, substituted or unsubstituted alkyl groups, substituted or unsubstituted alkoxy groups, substituted or unsubstituted amino groups, substituted or unsubstituted aryl groups, substituted or unsubstituted heterocyclic groups, substituted or unsubstituted aryloxy groups, silyl groups, and cyano groups.

In Formula (1), Ar₁ and Ar₂ each represent a substituted or unsubstituted aryl group.

In one aspect, R₁ to R₁₈ in Formula (1) each independently represent a hydrogen atom, a substituted or unsubstituted alkyl group, or a substituted or unsubstituted aryl group. In another aspect, in Formula (1), R₁, R₂, R₅, R₆, and R₁₁ to R₁₄ each independently represent a hydrogen atom or a substituted or unsubstituted aryl group; and R₃, R₄, R₇ to R₁₀, and R₁₅ to R₁₈ are hydrogen atoms; and Ar₁ and Ar₂ are aryl groups.

Specific examples of the substituents in Formula (1) will be described below.

Examples of the halogen atoms represented by R₁ to R₁₈ include, but not limited to, fluorine, chlorine, bromine, and iodine.

Examples of the alkyl groups represented by R₁ to R₁₈ include, but not limited to, methyl groups, ethyl groups, n-propyl groups, iso-propyl groups, n-butyl groups, tert-butyl groups, sec-butyl groups, cyclohexyl groups, octyl groups, 1-adamantyl groups, and 2-adamantyl groups.

Examples of the alkoxy groups represented by R₁ to R₁₈ include, but not limited to, methoxy groups, ethoxy groups, propoxy groups, 2-ethyl-octyloxy groups, and benzyloxy groups.

Examples of the amino groups represented by R₁ to R₁₈ include, but not limited to, N-methylamino groups, N-ethylamino groups, N,N-dimethylamino groups, N,N-diethylamino groups, N-methyl-N-ethylamino groups, N-benzylamino groups, N-methyl-N-benzylamino groups, N,N-dibenzylamino groups, anilino groups, N,N-diphenylamino groups, N,N-dinaphthylamino groups, N,N-difluorenylamino groups, N-phenyl-N-tolylamino groups, N,N-ditolylamino groups, N-methyl-N-phenylamino groups, N,N-dianisolylamino groups, N-mesityl-N-phenylamino groups, N,N-dimesitylamino groups, N-phenyl-N-(4-tert-butylphenyl)amino groups, and N-phenyl-N-(4-trifluoromethylphenyl)amino groups.

Examples of the aryl groups represented by R₁ to R₁₈ include, but not limited to, phenyl groups, naphthyl groups, indenyl groups, biphenyl groups, terphenyl groups, and fluorenyl groups.

Examples of the heterocyclic groups represented by R₁ to R₁₈ include, but not limited to, pyridyl groups, oxazolyl groups, oxadiazolyl groups, thiazolyl groups, thiadiazolyl groups, carbazolyl groups, acridinyl groups, phenanthrolyl groups, and piperidyl groups.

Examples of the aryloxy groups represented by R₁ to R₁₈ include, but not limited to, phenoxy groups, 4-tert-butylphenoxy groups, and thienyloxy groups.

Examples of the substituents which may be possessed by the above-mentioned alkyl groups, alkoxy groups, amino groups, aryl groups, heterocyclic groups, and aryloxy groups include, but not limited to, alkyl groups such as a methyl group, an ethyl group, an isopropyl group, and a tert-butyl group; aralkyl groups such as a benzyl group; aryl groups such as a phenyl group and a biphenyl group; heterocyclic groups such as a pyridyl group and a pyrrolyl group; amino groups such as a dimethylamino group, a diethylamino group, a dibenzylamino group, a diphenylamino group, and a ditolylamino group; alkoxy groups such as a methoxy group, an ethoxy group, and a propoxy group; aryloxy groups such as a phenoxy group; halogen atoms such as fluorine, chlorine, bromine, and iodine; and cyano groups.

Examples of the aryl groups represented by Ar₁ and Ar₂ include, but not limited to, phenyl groups, naphthyl groups, indenyl groups, biphenyl groups, terphenyl groups, and fluorenyl groups.

Examples of the substituent which may be possessed by the aryl group include, but not limited to, alkyl groups such as a methyl group, an ethyl group, an isopropyl group, and a tert-butyl group; aralkyl groups such as a benzyl group; aryl groups such as a phenyl group and a biphenyl group; heterocyclic groups such as a pyridyl group and a pyrrolyl group; amino groups such as a dimethylamino group, a diethylamino group, a dibenzylamino group, a diphenylamino group, and a ditolylamino group; alkoxy groups such as a methoxy group, an ethoxy group, and a propoxy group; aryloxy groups such as a phenoxy group; halogen atoms such as fluorine, chlorine, bromine, and iodine; and cyano groups.

A method of synthesizing the organic compound according to the present invention will now be described below. The organic compound according to the present invention can be synthesized in accordance with, for example, the following synthetic scheme. The following synthetic scheme is merely a specific example, and the method of synthesizing the organic compound according to the present invention is not limited thereto.

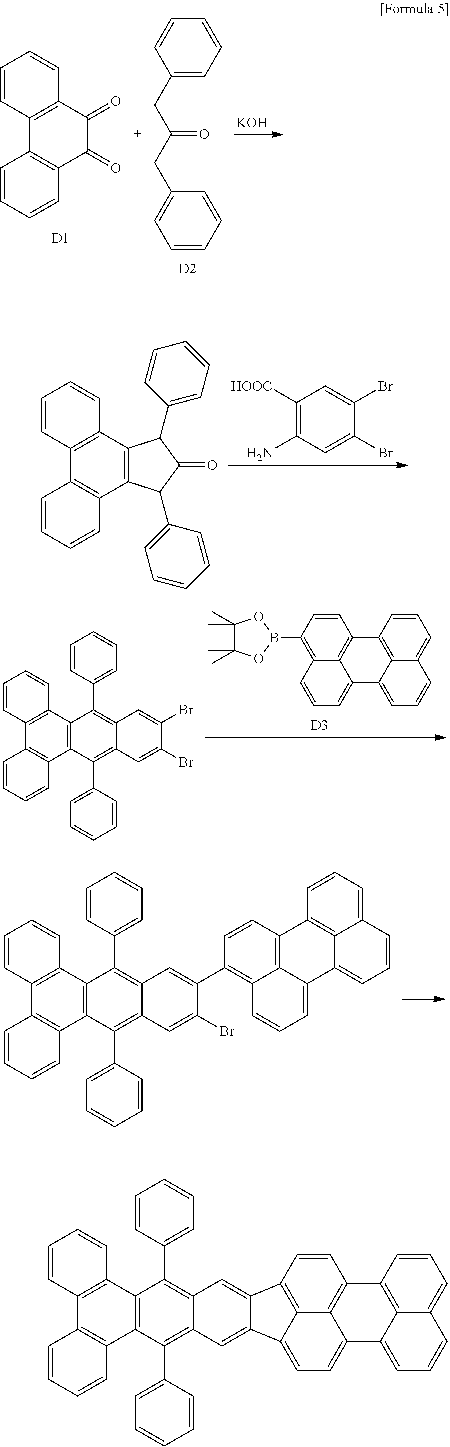

In the case of using the synthesis route shown in the above-mentioned synthesis scheme, any of hydrogen atoms of R₁ to R₁₈ in Formula (1) is substituted by a predetermined substituent by using compound D1, D2, or D3 having a substituent appropriately introduced. Examples of the introduced substituent include alkyl groups, halogen atoms, and phenyl groups.

In the case of synthesizing the organic compound according to the present invention using the above-mentioned synthesis scheme, various organic compounds can be synthesized by varying compounds D1, D2, and D3 shown in the synthesis scheme. Specific examples of the organic compound are shown in Table 1 together with compounds D1, D2, and D3 as the raw materials thereof.

TABLE 1

| Syn- | | | |
|---|---|---|---|
| the- | | | |
| sis | | | |
| ex- | | | |
| am- | | | |
| ple | D1 | D2 | D3 |
| 1 | 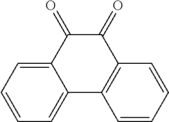 [SMILES: O=C1C(=O)c2ccccc2-c2ccccc21] | 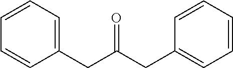 [SMILES: O=C(Cc1ccccc1)Cc1ccccc1] | 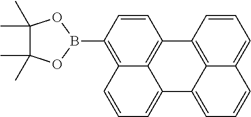 [SMILES: CC1(C)OB(c2ccc3c4cccc5cccc(c6cccc2c63)c54)OC1(C)C] |
| 2 | 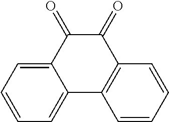 [SMILES: O=C1C(=O)c2ccccc2-c2ccccc21] | 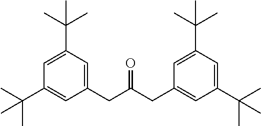 [SMILES: CC(C)(C)c1cc(CC(=O)Cc2cc(C(C)(C)C)cc(C(C)(C)C)c2)cc(C(C)(C)C)c1] | 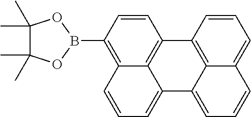 [SMILES: CC1(C)OB(c2ccc3c4cccc5cccc(c6cccc2c63)c54)OC1(C)C] |
| 3 | 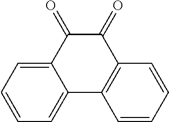 [SMILES: O=C1C(=O)c2ccccc2-c2ccccc21] | 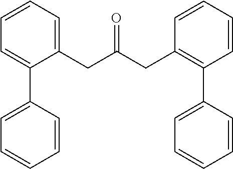 [SMILES: O=C(Cc1ccccc1-c1ccccc1)Cc1ccccc1-c1ccccc1] | 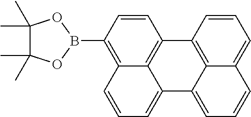 [SMILES: CC1(C)OB(c2ccc3c4cccc5cccc(c6cccc2c63)c54)OC1(C)C] |
| 4 | 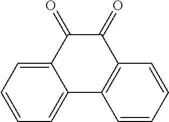 [SMILES: O=C1C(=O)c2ccccc2-c2ccccc21] | 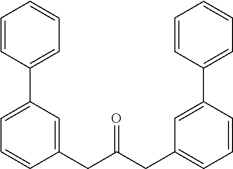 [SMILES: O=C(Cc1cccc(-c2ccccc2)c1)Cc1cccc(-c2ccccc2)c1] | 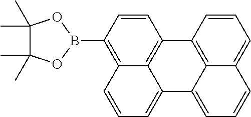 [SMILES: CC1(C)OB(c2ccc3c4cccc5cccc(c6cccc2c63)c54)OC1(C)C] |
| 5 | 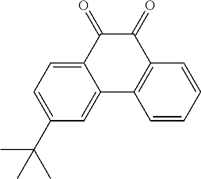 [SMILES: CC(C)(C)c1ccc2c(c1)-c1ccccc1C(=O)C2=O] | 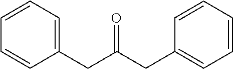 [SMILES: O=C(Cc1ccccc1)Cc1ccccc1] | 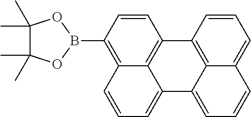 [SMILES: CC1(C)OB(c2ccc3c4cccc5cccc(c6cccc2c63)c54)OC1(C)C] |
| 6 | 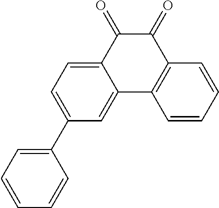 [SMILES: O=C1C(=O)c2ccc(-c3ccccc3)cc2-c2ccccc21] | 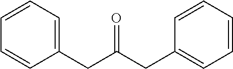 [SMILES: O=C(Cc1ccccc1)Cc1ccccc1] | 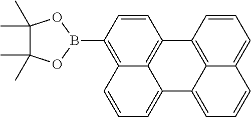 [SMILES: CC1(C)OB(c2ccc3c4cccc5cccc(c6cccc2c63)c54)OC1(C)C] |
| 7 | 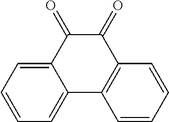 [SMILES: O=C1C(=O)c2ccccc2-c2ccccc21] | 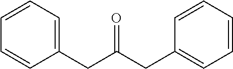 [SMILES: O=C(Cc1ccccc1)Cc1ccccc1] | 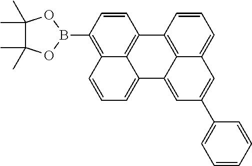 [SMILES: CC1(C)OB(c2ccc3c4cccc5cc(-c6ccccc6)cc(c6cccc2c36)c54)OC1(C)C] |
| 8 | 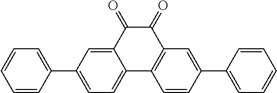 [SMILES: O=C1C(=O)c2cc(-c3ccccc3)ccc2-c2ccc(-c3ccccc3)cc21] | 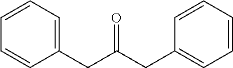 [SMILES: O=C(Cc1ccccc1)Cc1ccccc1] | 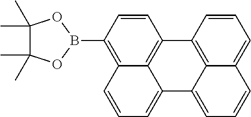 [SMILES: CC1(C)OB(c2ccc3c4cccc5cccc(c6cccc2c63)c54)OC1(C)C] |
| 9 | 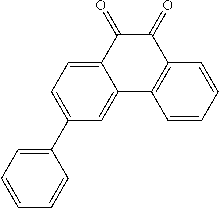 [SMILES: O=C1C(=O)c2ccc(-c3ccccc3)cc2-c2ccccc21] | 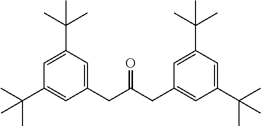 [SMILES: CC(C)(C)c1cc(CC(=O)Cc2cc(C(C)(C)C)cc(C(C)(C)C)c2)cc(C(C)(C)C)c1] | 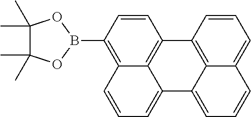 [SMILES: CC1(C)OB(c2ccc3c4cccc5cccc(c6cccc2c63)c54)OC1(C)C] |

| Synthesis | Synthesized | Example |
|---|---|---|
| example | compound | Compound |
| 1 | 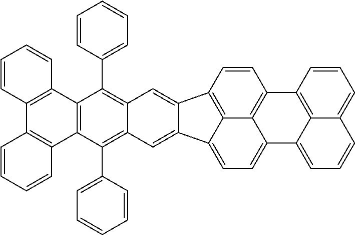 [SMILES: c1ccc(-c2c3cc4c(cc3c(-c3ccccc3)c3c5ccccc5c5ccccc5c23)-c2ccc3c5cccc6cccc(c7ccc-4c2c73)c65)cc1] | A1 |
| 2 | 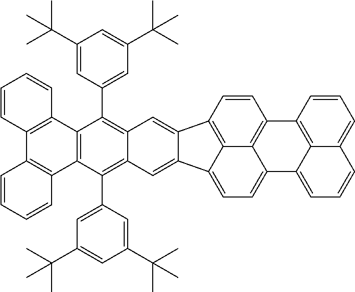 [SMILES: CC(C)(C)c1cc(-c2c3cc4c(cc3c(-c3cc(C(C)(C)C)cc(C(C)(C)C)c3)c3c5ccccc5c5ccccc5c23)-c2ccc3c5cccc6cccc(c7ccc-4c2c73)c65)cc(C(C)(C)C)c1] | A4 |
| 3 | 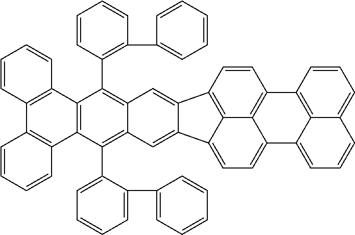 [SMILES: c1ccc(-c2ccccc2-c2c3cc4c(cc3c(-c3ccccc3-c3ccccc3)c3c5ccccc5c5ccccc5c23)-c2ccc3c5cccc6cccc(c7ccc-4c2c73)c65)cc1] | A5 |
| 4 | 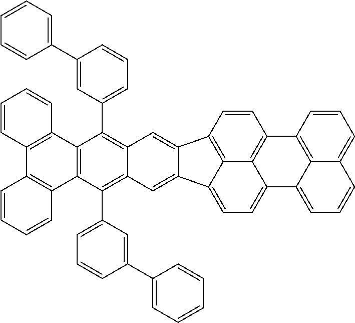 [SMILES: c1ccc(-c2cccc(-c3c4cc5c(cc4c(-c4cccc(-c6ccccc6)c4)c4c6ccccc6c6ccccc6c34)-c3ccc4c6cccc7cccc(c8ccc-5c3c84)c76)c2)cc1] | A6 |
| 5 | 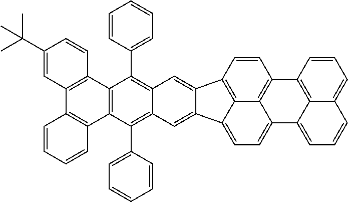 [SMILES: CC(C)(C)c1ccc2c(c1)c1ccccc1c1c(-c3ccccc3)c3cc4c(cc3c(-c3ccccc3)c21)-c1ccc2c3cccc5cccc(c6ccc-4c1c62)c53] | A10 |
| 6 | 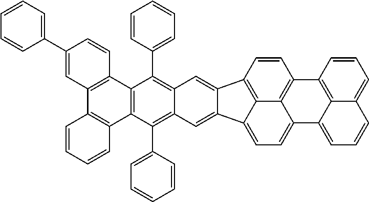 [SMILES: c1ccc(-c2ccc3c(c2)c2ccccc2c2c(-c4ccccc4)c4cc5c(cc4c(-c4ccccc4)c32)-c2ccc3c4cccc6cccc(c7ccc-5c2c73)c64)cc1] | A12 |
| 7 | 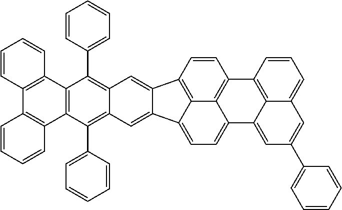 [SMILES: c1ccc(-c2cc3cccc4c5ccc6c7c(ccc(c(c2)c34)c75)-c2cc3c(-c4ccccc4)c4c5ccccc5c5ccccc5c4c(-c4ccccc4)c3cc2-6)cc1] | A13 |
| 8 | 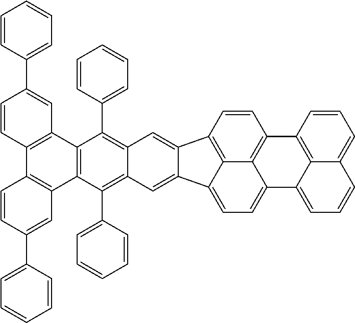 [SMILES: c1ccc(-c2ccc3c4ccc(-c5ccccc5)cc4c4c(-c5ccccc5)c5cc6c(cc5c(-c5ccccc5)c4c3c2)-c2ccc3c4cccc5cccc(c7ccc-6c2c37)c54)cc1] | A14 |
| 9 | 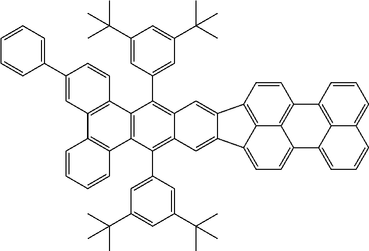 [SMILES: CC(C)(C)c1cc(-c2c3cc4c(cc3c(-c3cc(C(C)(C)C)cc(C(C)(C)C)c3)c3c5ccc(-c6ccccc6)cc5c5ccccc5c23)-c2ccc3c5cccc6cccc(c7ccc-4c2c73)c65)cc(C(C)(C)C)c1] | A17 |

Characteristics of the organic compound according to the present invention will be described below.

The present inventors have focused on basic skeleton itself in designing the compound. Specifically, the inventors have tried to provide a compound of which basic skeleton compound has an emission wavelength within a desired emission wavelength range and has a structure that can inhibit molecular packing. Throughout the description, the term “molecular packing” refers to a phenomenon that molecules overlap each other by intermolecular interaction.

In condensed ring aromatic compounds, the flatness of the molecular skeleton is generally high, and thereby the intermolecular interaction is strong to enhance molecular packing. This molecular packing causes crystallization and formation of excimers, which are disadvantageous phenomena from the viewpoints of durability and luminous efficiency in organic light-emitting devices. Accordingly, it is necessary to inhibit the molecular packing. Specific examples of such countermeasures include a method of increasing the intermolecular distance by introducing a bulky substituent into the basic skeleton and a method decreasing the flatness of the basic skeleton itself. However, the method of introducing a bulky substituent into the basic skeleton is accompanied by an increase in molecular weight and may therefore impair the sublimability of the compound.

In the method of decreasing the flatness of basic skeleton itself, in other words, in a method of forming distortion in the molecular plane to some extent, the molecular packing of, for example, the basic skeleton can be inhibited. For example, the molecular plane of Compound 2 shown in Table 2 has a certain degree of distortion.

TABLE 2

| | Structural | Perpendicular | |
|---|---|---|---|
| Compound | formula | direction | Parallel direction |
| 1 | 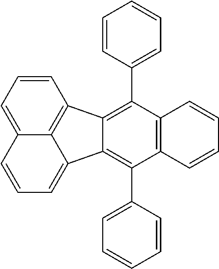 [SMILES: c1ccc(-c2c3c(c(-c4ccccc4)c4ccccc24)-c2cccc4cccc-3c24)cc1] | 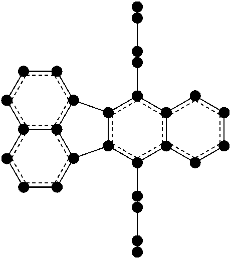 | 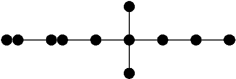 |
| 2 | 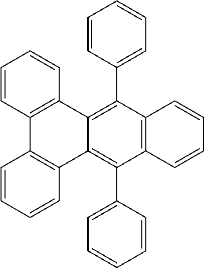 [SMILES: c1ccc(-c2c3ccccc3c(-c3ccccc3)c3c4ccccc4c4ccccc4c23)cc1] | 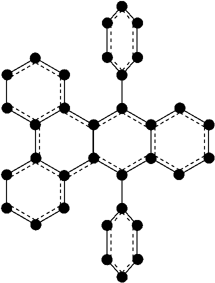 | 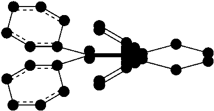 |

In Table 2, Compound 1 has phenyl groups as substituents at the 9- and 14-positions of benzofluoranthene serving as the basic skeleton. As shown in Table 2, the flatness of Compound 1 is maintained even if the phenyl groups are introduced as substituents. On the contrary, Compound 2 has phenyl groups as substituents at the 9- and 14-positions of dibenzanthracene serving as the basic skeleton. As shown in Table 2, in Compound 2, the flatness of the molecule is broken by introduction of the phenyl groups as substituents to cause distortion as the entire molecule. This distortion functions so as to inhibit molecular packing.

As a method for obtaining a desired emission wavelength, it is known to provide a substituent to the basic skeleton. Unfortunately, the introduction of a substituent may deteriorate the stability of the compound. However, in the organic compound according to the present invention, since the basic skeleton itself emits light in a desired wavelength range, there is no necessity to positively introducing a substituent to the basic skeleton. In the present invention, the term “desired wavelength range” refers to a yellow range, specifically, a wavelength range of 570 to 590 nm.

Characteristics of the organic compound according to the present invention will be described below while comparing with comparative compounds having structure similar to the organic compound of the present invention. Specifically, the comparative compounds are those represented by the following Formulae (2) and (3).

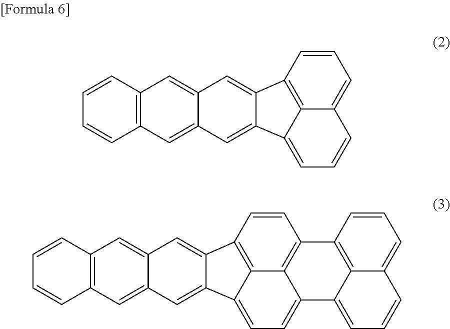

Herein, the organic compound according to the present invention is a compound having a basic skeleton represented by the following Formula (4).

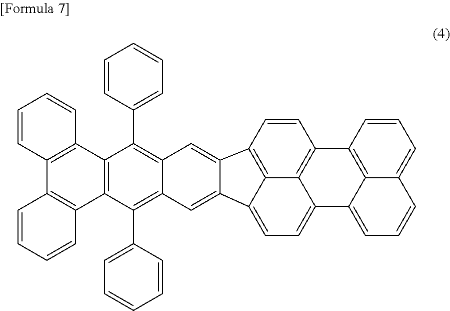 [SMILES: c1ccc(-c2c3cc4c(cc3c(-c3ccccc3)c3c5ccccc5c5ccccc5c23)-c2ccc3c5cccc6cccc(c7ccc-4c2c73)c65)cc1]

The light-emitting characteristics and flatness of the molecular skeleton of the compound represented by Formula (4) were compared with those of a compound in which the compound represented by Formula (2) is substituted by phenyl groups and a compound in which the compound represented by Formula (3) is substituted by phenyl groups. Table 3 shows the results. The flatness of the molecular skeleton was determined by molecular orbital calculation.

TABLE 3

| | | Maximum | |
|---|---|---|---|
| | | emission | |
| | Structural | wavelength | Perpendicular |
| Compound | formula | (nm) | direction |
| a | 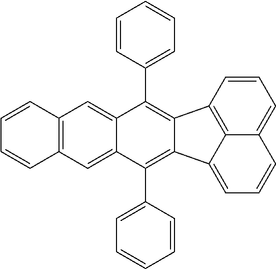 [SMILES: c1ccc(-c2c3c(c(-c4ccccc4)c4cc5ccccc5cc24)-c2cccc4cccc-3c24)cc1] | 432 | 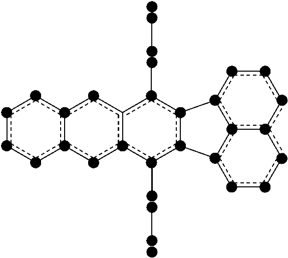 |
| b | 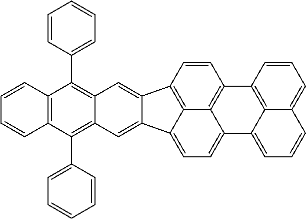 [SMILES: c1ccc(-c2c3ccccc3c(-c3ccccc3)c3cc4c(cc23)-c2ccc3c5cccc6cccc(c7ccc-4c2c37)c65)cc1] | 556 | 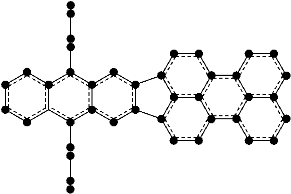 |
| c | 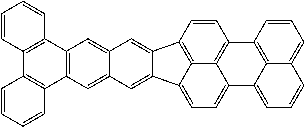 [SMILES: c1ccc2c(c1)c1ccccc1c1cc3cc4c(cc3cc21)-c1ccc2c3cccc5cccc(c6ccc-4c1c26)c53] | 544 | 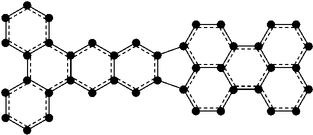 |
| d | 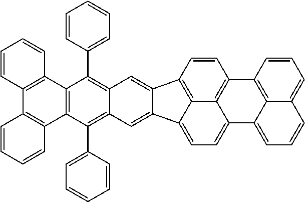 [SMILES: c1ccc(-c2c3cc4c(cc3c(-c3ccccc3)c3c5ccccc5c5ccccc5c23)-c2ccc3c5cccc6cccc(c7ccc-4c2c73)c65)cc1] | 554 | 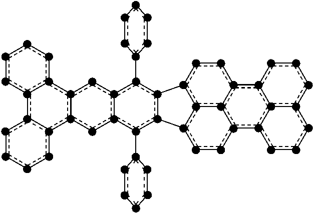 |

| Compound | Parallel direction |
|---|---|
| a | 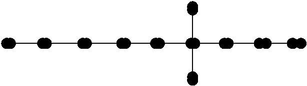 |
| b | 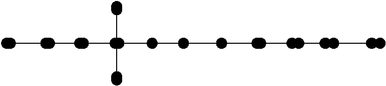 |
| c | 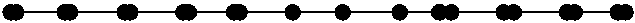 |
| d | 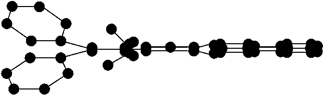 |

In Table 3, Compound a emits violet light. Thus, Compound a has highly different physical properties from those of the organic compound according to the present invention in light-emitting characteristics (luminescent color), and is unsuitable for emitting yellow light.

As shown in Table 3, the light emitted by Compound b and Compound c is yellow, which is the same as the luminescent color of Compound d, which belongs to the organic compound according to the present invention.

However, as shown in Table 3, in Compounds b and c, the flatness of the molecular skeleton is high to enhance the molecular packing. Accordingly, it is suggested that the change in emission wavelength becomes large when Compound b or c is used in a high concentration. A change in emission wavelength herein is caused by relaxation of excitation energy due to intermolecular interaction, and the change therefore means an increase in long-wavelength component of emission wavelength. Since the emitted light energy is lost by the relaxation of excitation energy, the increase in component with a long emission wavelength is the same meaning as a decrease in luminous efficiency due to concentration quenching.

Sample A and Sample B were produced for Compounds b and d shown in Table 3 as shown below, and PL spectra thereof were measured.

Sample A: toluene solution (concentration: 1×10⁻⁵ mol/L), and
Sample B: doped film in which the host material is that shown by the following Formula (5) and the guest material is Compound b or d.

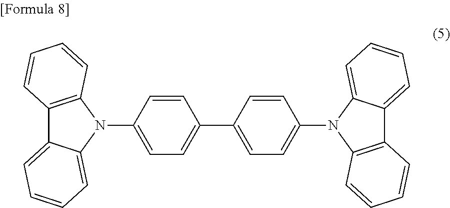 [SMILES: c1ccc2c(c1)c1ccccc1n2-c1ccc(-c2ccc(-n3c4ccccc4c4ccccc43)cc2)cc1]

(the doped film as Sample B has a weight ratio of the host material and the guest material of 90:10 and was produced through co-deposition by resistance heating in a vacuum chamber of a degree of vacuum of 5.0×10⁻⁵ Pa.)

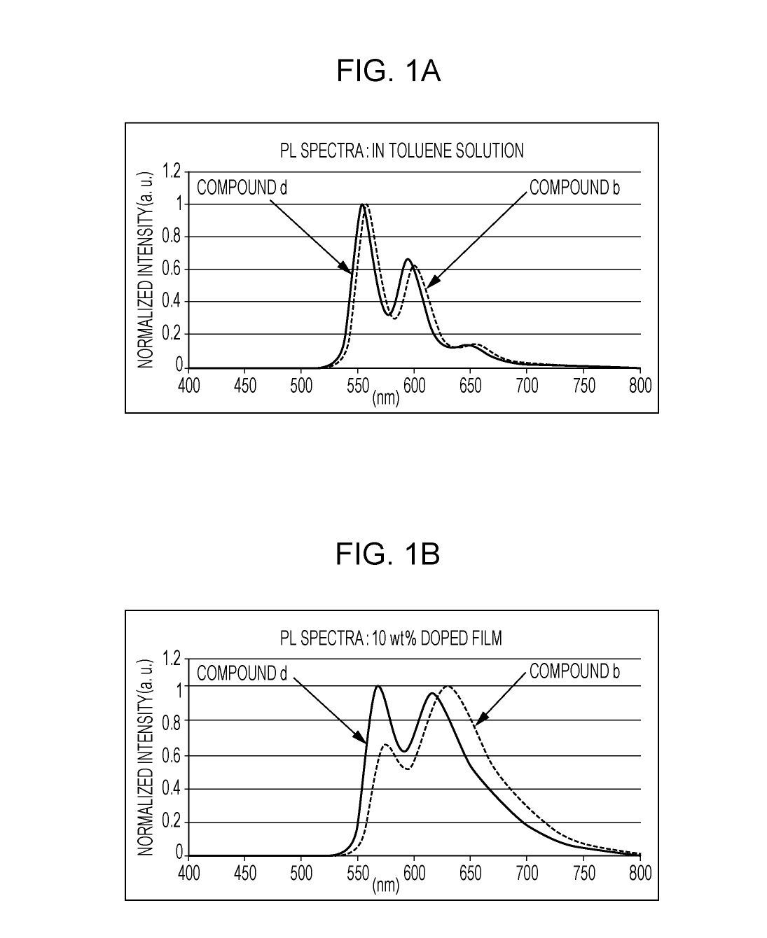

FIG. 1A shows PL spectra of Sample A, and FIG. 1B shows PL spectra of Sample B.

As shown in FIG. 1A, the results are that the emission spectral shapes of Compounds b and d in Sample A (in toluene solution) are similar to each other, whereas, as shown in FIG. 1B, the emission spectral shapes of Compounds b and d in Sample B (doped film) differ from each other. That is, as shown in FIG. 1B, the maximum emission wavelength of emission spectrum in the doped film of Compound b is the second peak at the longer wavelength side. On the contrary, the maximum emission wavelength of emission spectrum in the doped film of Compound d is the first peak on the shorter wavelength side as in emission spectra in the toluene solution.

From the above-described results, in Compound b shown in Table 3, a decrease in efficiency due to concentration quenching is concerned. Therefore, Compound b is not suitable as a light-emitting material. On the other hand, it was revealed that Compound d shown in Table 3 emits yellow light (554 nm), shows a high quantum yield, and inhibits molecular packing by non-flatness of the molecular skeleton.

In the organic compound according to the present invention, aryl groups that are introduced at the 7- and 16-positions of the skeleton shown below are important factors for giving non-flatness to the molecular skeleton.

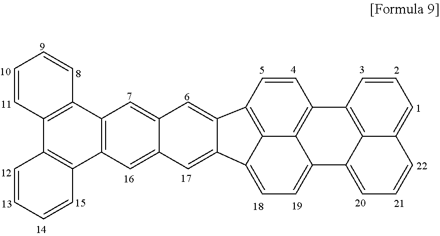 [SMILES: c1ccc2c(c1)c1ccccc1c1cc3cc4c(cc3cc21)-c1ccc2c3cccc5cccc(c6ccc-4c1c26)c53]

This relates to that the flatness of the molecular skeleton of Compound d in which aryl groups are introduced at the 7- and 16-positions of the skeleton highly differs from that of a compound in which no substituents are introduced at the 7- and 16-positions of the skeleton, i.e., Compound c shown in Table 3. Incidentally, in Compound c, the flatness of the molecular skeleton is high, and, therefore, Compound c cannot inhibit molecular packing. Accordingly, a high concentration of Compound c causes concentration quenching due to the molecular packing, and the luminous efficiency decreases.

As described above, Compound d shown in Table 3 can reduce concentration quenching due to molecular packing even if Compound d is used as the constituent material of an organic light-emitting device in a high concentration. Consequently, the original characteristics of the material can be incorporated in the performance of the device without any change.

Molecular packing can be inhibited to some extent by introduction of a bulky substituent. However, Compounds b and c shown in Table 3 themselves have large molecular weights, and the molecular weights are further increased by the introduction of substituents, which may decrease sublimability. Accordingly, it is difficult to introduce substituents effective for inhibition of molecular packing.

In addition, since the organic compound according to the present invention has a five-membered ring structure in the basic skeleton, the HOMO level is deep, that is, the oxidation potential is high. Therefore, the organic compound according to the present invention is stable against oxidation.

The organic compound according to the present invention does not have a heteroatom such as a nitrogen atom in the basic skeleton. This also contributes to the high oxidation potential, that is, the stability against oxidation of the organic compound.

In the organic compound according to the present invention, both the HOMO level and the LUMO level of the basic skeleton are deep.

Furthermore, a material that emits red light can be obtained by inducing a substituent that elongates the emission wavelength to the basic skeleton of the organic compound according to the present invention. The compound showing a long emission wavelength also has the basic skeleton that is the same as that of the organic compound according to the present invention and is therefore stable against oxidation.

Specific examples of the organic compound according to the present invention are shown below, but the present invention is not limited thereto.

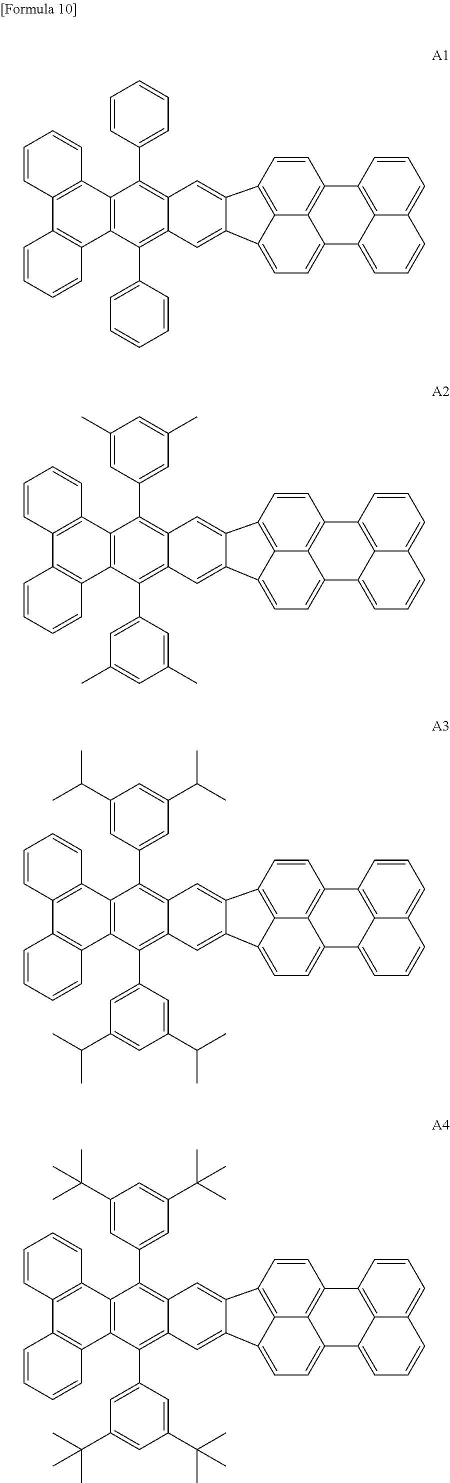

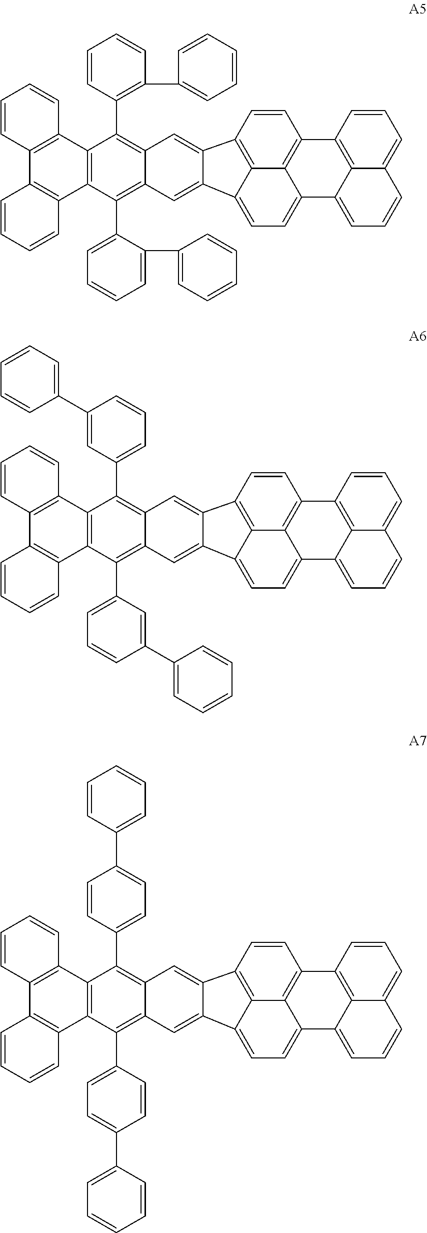

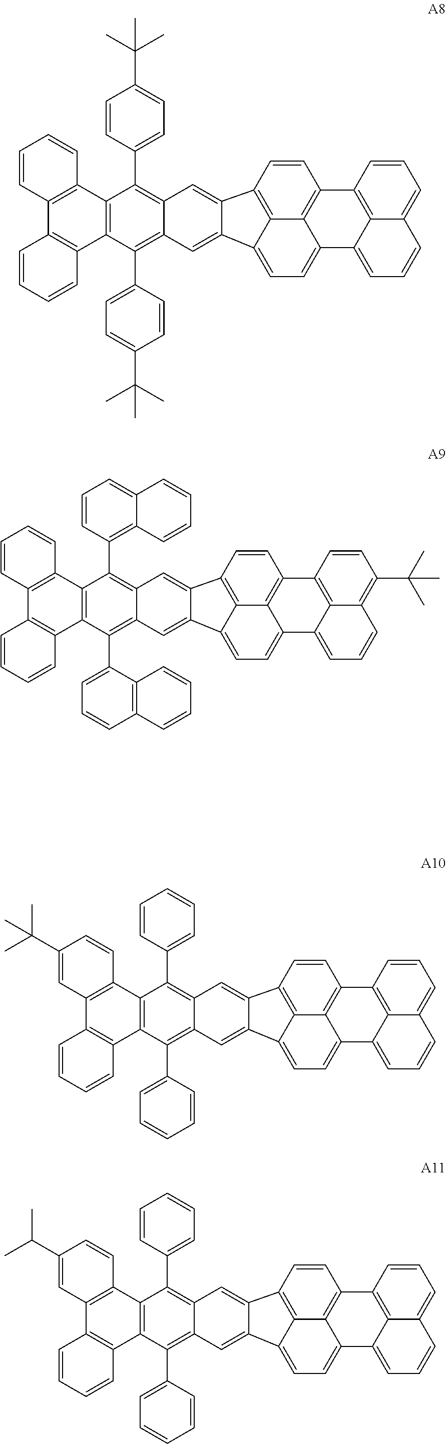

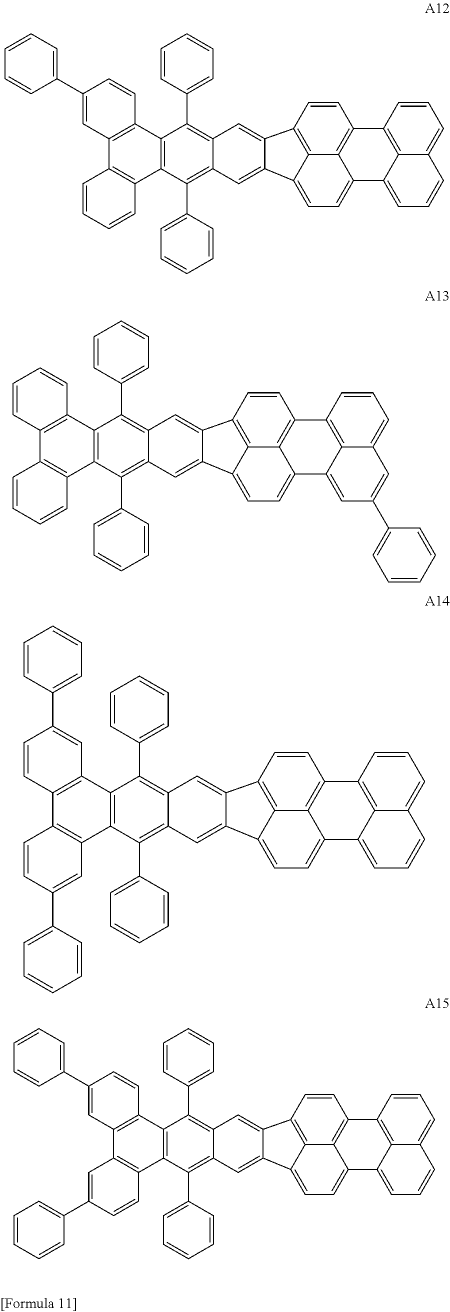

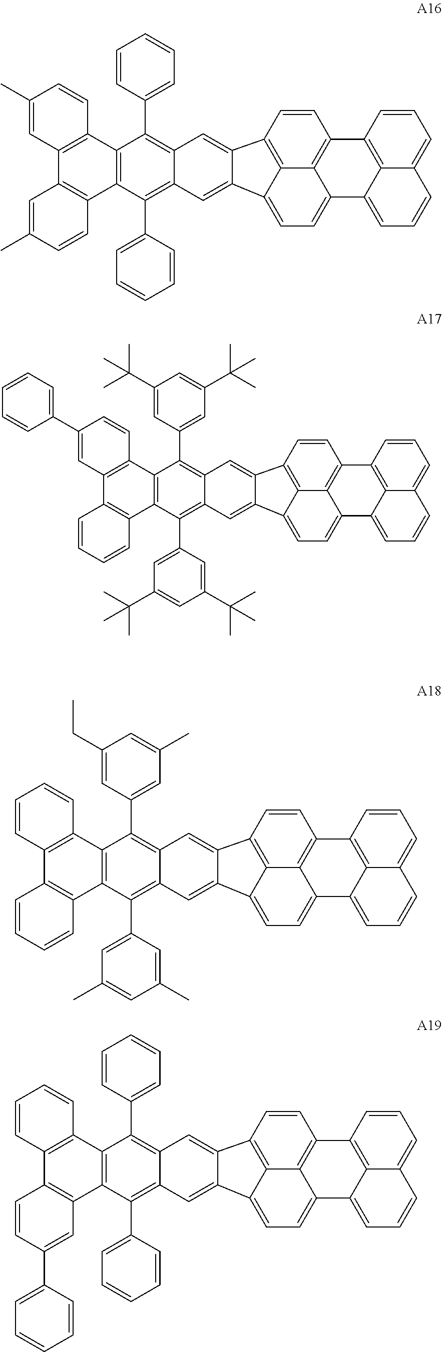

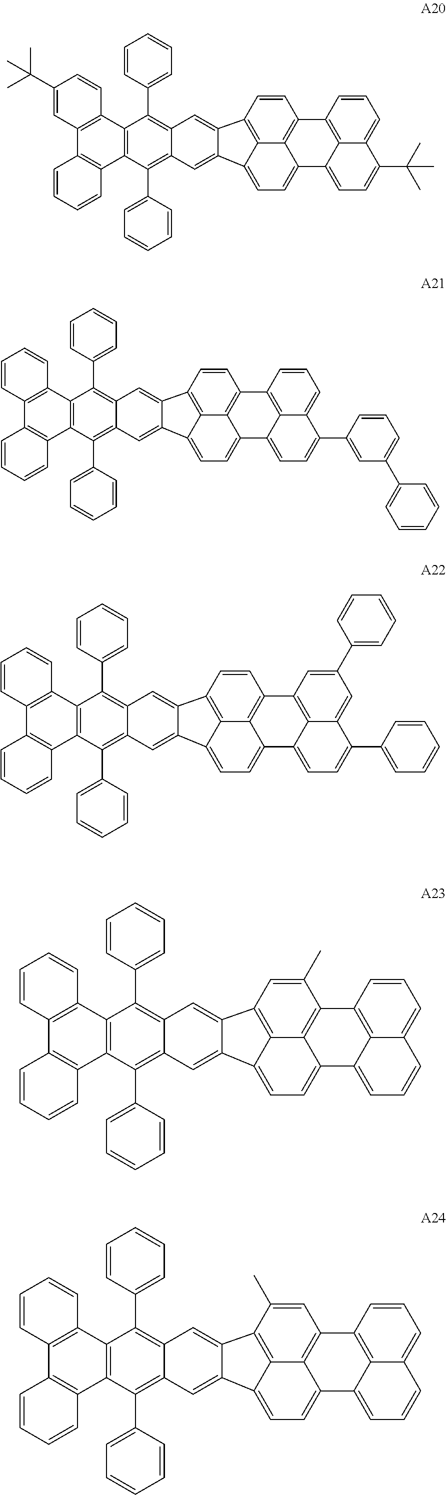

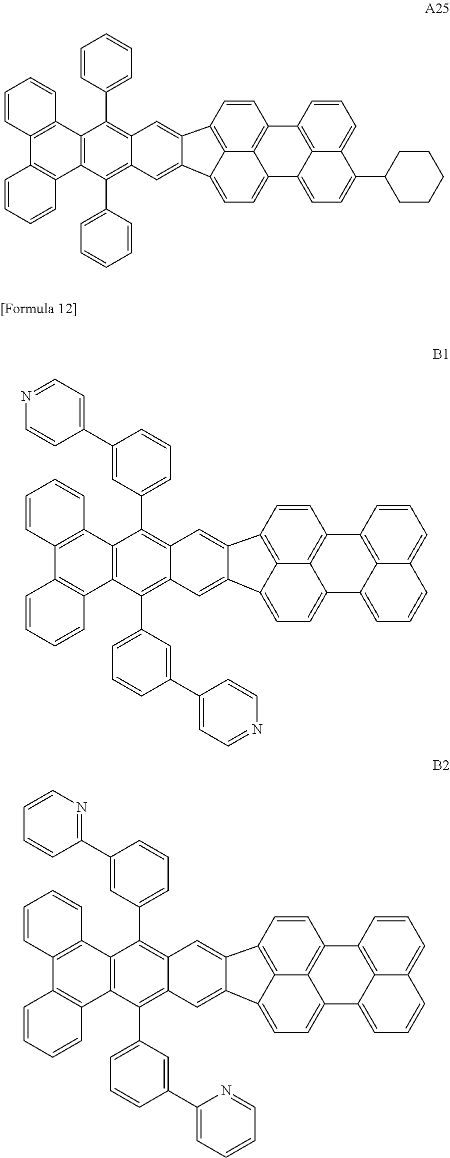

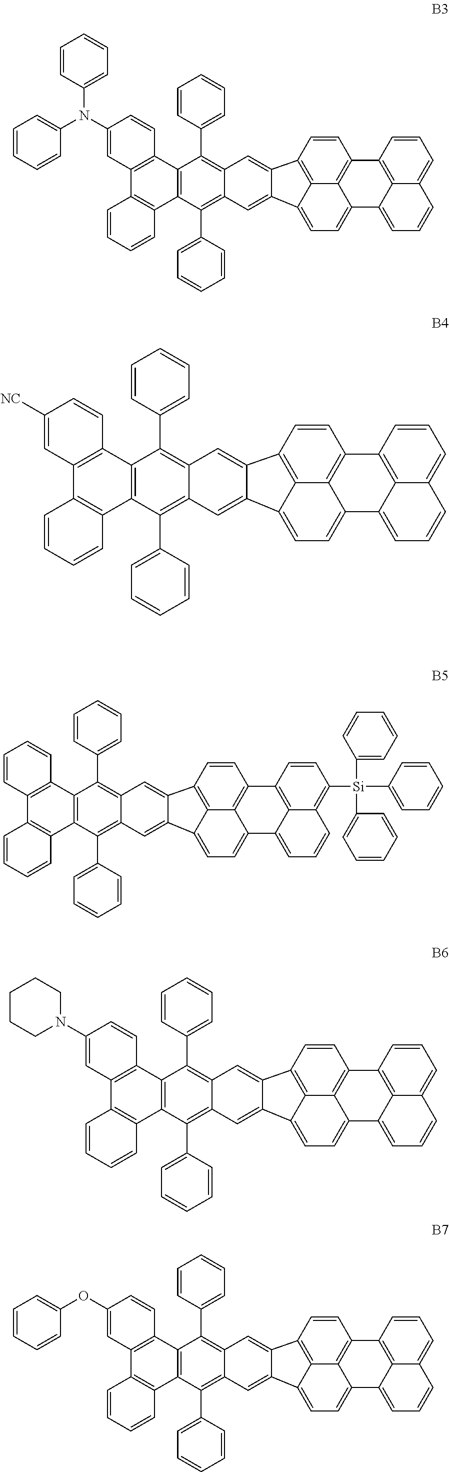

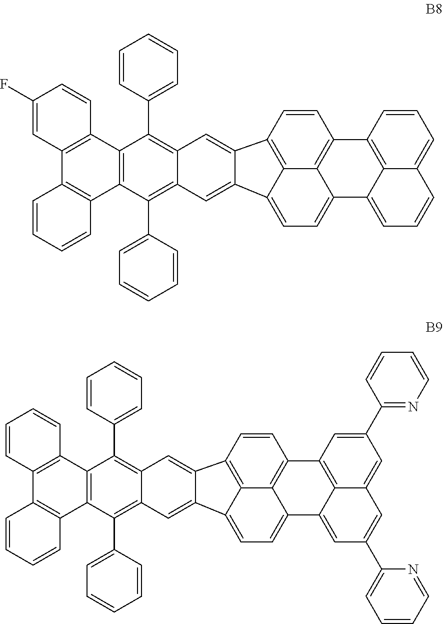 [SMILES: Fc1ccc2c(c1)c1ccccc1c1c(-c3ccccc3)c3cc4c(cc3c(-c3ccccc3)c21)-c1ccc2c3cccc5cccc(c6ccc-4c1c62)c53 ; c1ccc(-c2c3cc4c(cc3c(-c3ccccc3)c3c5ccccc5c5ccccc5c23)-c2ccc3c5cc(-c6ccccn6)cc6cc(-c7ccccn7)cc(c7ccc-4c2c73)c65)cc1]

Among the example compounds, in the compounds belonging to Group A, the entire molecule is constituted of hydrocarbons only. Herein, the compounds constituted of hydrocarbons only have low HOMO levels. Accordingly, the compounds belonging to Group A are regarded as compounds having low oxidation potentials, that is, having high stability against oxidation. Consequently, among the organic compounds according to the present invention, the compounds constituted of hydrocarbons only belonging to Group A are high in molecular stability, in particular, anti-oxidation stability.

Among the example compounds, the compounds belonging to Group B include heteroatoms. Therefore, the oxidation potential or intermolecular interaction changes depending on the type of the substituent. Furthermore, in the case of a substituent having a heteroatom, it is possible to use the compound in a high concentration of 100% as an electron-transporting, hole-transporting, or hole-trapping light-emitting material.

The example compounds shown above emit yellow light by the basic skeletons themselves. The organic compounds according to the present invention including the example compounds can be used as constituent materials of organic light-emitting devices. Specifically, the compounds can be used, for example, as the host material contained in a light-emitting layer, an electron-injecting/transporting material contained in an electron-transporting layer or an electron-injecting layer, a hole-injecting/transporting material contained in a hole-transporting layer or a hole-injecting layer, and a constituent material of a hole/exciton-blocking layer.

An organic light-emitting device according to this embodiment will be described below. The organic light-emitting device according to the embodiment includes at least a pair of electrodes composed of an anode and a cathode and an organic compound layer disposed between the anode and the cathode. The organic light-emitting device is an electronic element that emits light by the following processes (a) to (c):

(a) a process of injection of carriers (holes and electrons) from the anode and the cathode;

(b) a process of recombination of the carriers in an organic light-emitting compound contained in an organic compound layer; and

(c) a process of returning of the excitons of the organic light-emitting compound generated by the recombination to the ground state.

In the organic light-emitting device according to the embodiment, the organic compound according to the present invention is contained in the organic compound layer. Herein, the organic compound layer is a monolayer or a laminate of a plurality of layers having at least a light-emitting layer. When the organic compound layer is a laminate composed of a plurality of layers, the laminate includes, in addition to a light-emitting layer, for example, any of a hole-injecting layer, a hole-transporting layer, a hole/exciton-blocking layer, an electron-transporting layer, and an electron-injecting layer.

Specific examples of the organic light-emitting device according to the embodiment include:

(i) (substrate/)anode/light-emitting layer/cathode,
(ii) (substrate/)anode/hole-transporting layer/electron-transporting layer/cathode,
(iii)(substrate/)anode/hole-transporting layer/light-emitting layer/electron-transporting layer/cathode,
(iv) (substrate/)anode/hole-injecting layer/hole-transporting layer/light-emitting layer/electron-transporting layer/cathode, and
(v)(substrate/)anode/hole-transporting layer/light-emitting layer/hole- and exciton-blocking layer/electron-transporting layer/cathode.

The above-mentioned five specific structures are only basic device configurations, and the organic light-emitting device using the organic compound according to the present invention is not limited these configurations. Various layer structure, for example, a structure having an insulating layer, an adhesion, or an interference layer at the interface between an electrode and an organic compound layer or a structure having an electron-transporting layer or a hole-transporting layer constituted of two layers having different ionization potentials can be employed. The light-emitting layer may be a monolayer or a laminate composed of a plurality of layers made of different constituent materials.

In the organic light-emitting device according to the embodiment, the organic compound according to the present invention is contained in any of the above-mentioned organic compound layers (e.g., hole-injecting layer, hole-transporting layer, light-emitting layer, hole/exciton-blocking layer, electron-transporting layer, and electron-injecting layer). In particular, the organic compound according to the present invention can be contained in the light-emitting layer.

In the case of a light-emitting layer containing the organic compound according to the present invention, the light-emitting layer may be formed of the organic compound according to the present invention only or may be formed of a plurality of components.

In the case of a light-emitting layer formed of a plurality of components, the light-emitting layer is constituted of a compound serving as a main component and a compound serving as an accessory component. Herein, the main component has a largest weight ratio among the compounds constituting a light-emitting layer, and the material as the main component is called host material. The accessory component has a weight ratio smaller than that of the main component and is classified into, for example, a dopant (guest) material, a light-emitting assist material, and a charge injection material depending on the function possessed by the material. In the light-emitting device of the present invention, the organic compound according to the present invention may be used as the main component of a light-emitting layer or may be used as an accessory component of a light-emitting layer.

The present inventors have performed various investigations and have found that an organic light-emitting device using the organic compound according to the present invention as the host or guest material of a light-emitting layer is excellent in luminous efficiency, luminance, and durability. In particular, it has been found that an organic light-emitting device using the organic compound according to the present invention as the guest material of a light-emitting layer has an optical output with high efficiency and high luminance and shows significantly high durability.

Thus, the organic compound according to the present invention can be used as a guest material of a light-emitting layer of an organic light-emitting device, in particular, as a guest material of a yellow light-emitting device. Such use of the organic compound of the present invention provides an organic light-emitting device that emits yellow light by the emission of the organic compound according to the present invention.

In the case of using the organic compound according to the present invention as a guest material of a light-emitting layer, the amount of the guest material relative to the amount of the host material can be 0.01 wt % or more and 20 wt % or less, such as 0.2 wt % or more and 5 wt % or less, based on the total amount of the materials constituting the light-emitting layer.

In the case of using the organic compound according to the present invention as a guest material of a light-emitting layer, the host material can have a LUMO level deeper than that of the organic compound according to the present invention. By doing so, though the organic compound according to the present invention has a deep LUMO level, the compound can satisfactorily receive electrons supplied to the host material of the light-emitting layer.

Herein, in addition to the organic compound according to the present invention, for example, a known low-molecular or high-molecular hole-injecting/transporting compound, host material, light-emitting compound, or electron-injecting/transporting compound can be optionally used together with the organic compound.

Examples of these compounds will be shown below.

As the hole-injecting compound or the hole-transporting compound, a material having high hole mobility can be used. Examples of the low or high molecular material having hole-injecting or transporting ability include, but not limited to, triarylamine derivatives, phenylenediamine derivatives, stilbene derivatives, phthalocyanine derivatives, porphyrin derivatives, poly(vinylcarbazole), poly(thiophene), and other electrically conductive polymers.

Examples of the host material contained in a light-emitting layer include compounds shown in Table 4.

TABLE 4
H1 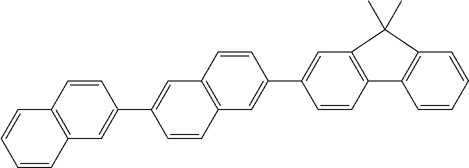 [SMILES: CC1(C)c2ccccc2-c2ccc(-c3ccc4cc(-c5ccc6ccccc6c5)ccc4c3)cc21]
H2 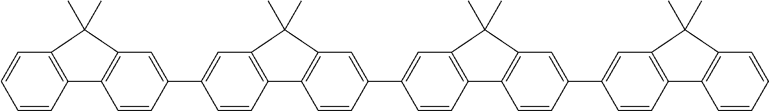 [SMILES: CC1(C)c2ccccc2-c2ccc(-c3ccc4c(c3)C(C)(C)c3cc(-c5ccc6c(c5)C(C)(C)c5cc(-c7ccc8c(c7)C(C)(C)c7ccccc7-8)ccc5-6)ccc3-4)cc21]
H3 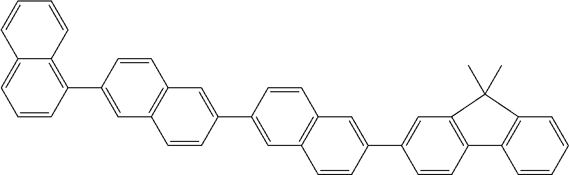 [SMILES: CC1(C)c2ccccc2-c2ccc(-c3ccc4cc(-c5ccc6cc(-c7cccc8ccccc78)ccc6c5)ccc4c3)cc21]
H4 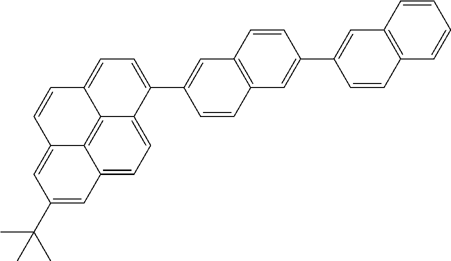 [SMILES: CC(C)(C)c1cc2ccc3ccc(-c4ccc5cc(-c6ccc7ccccc7c6)ccc5c4)c4ccc(c1)c2c34]
H5 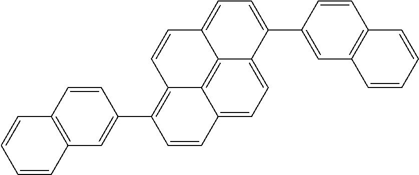 [SMILES: c1ccc2cc(-c3ccc4ccc5c(-c6ccc7ccccc7c6)ccc6ccc3c4c65)ccc2c1]
H6 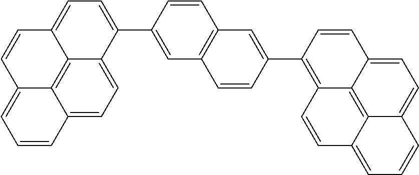 [SMILES: c1cc2ccc3ccc(-c4ccc5cc(-c6ccc7ccc8cccc9ccc6c7c89)ccc5c4)c4ccc(c1)c2c34]
H7 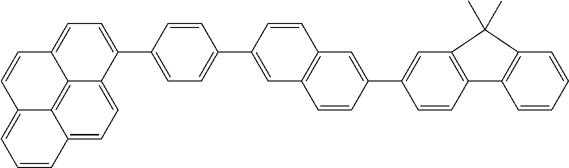 [SMILES: CC1(C)c2ccccc2-c2ccc(-c3ccc4cc(-c5ccc(-c6ccc7ccc8cccc9ccc6c7c89)cc5)ccc4c3)cc21]
H8 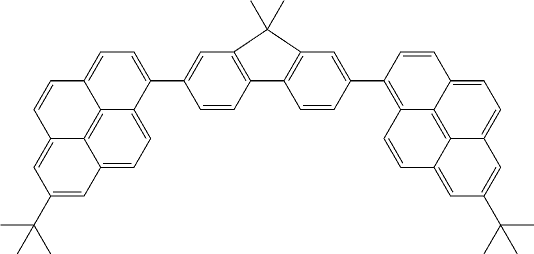 [SMILES: CC(C)(C)c1cc2ccc3ccc(-c4ccc5c(c4)C(C)(C)c4cc(-c6ccc7ccc8cc(C(C)(C)C)cc9ccc6c7c89)ccc4-5)c4ccc(c1)c2c34]
H9 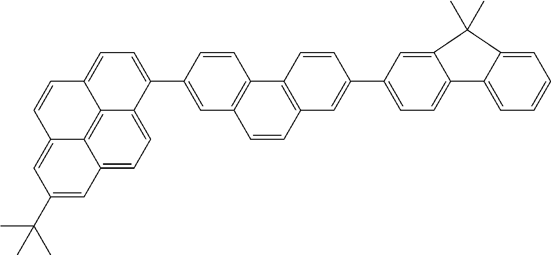 [SMILES: CC(C)(C)c1cc2ccc3ccc(-c4ccc5c(ccc6cc(-c7ccc8c(c7)C(C)(C)c7ccccc7-8)ccc65)c4)c4ccc(c1)c2c34]
H10 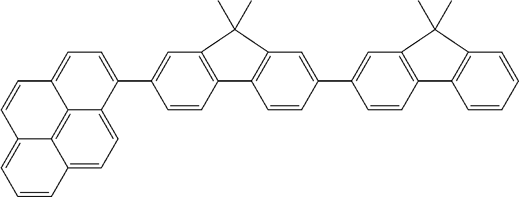 [SMILES: CC1(C)c2ccccc2-c2ccc(-c3ccc4c(c3)C(C)(C)c3cc(-c5ccc6ccc7cccc8ccc5c6c78)ccc3-4)cc21]
H11 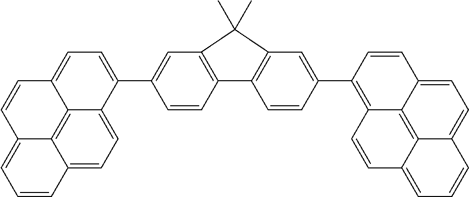 [SMILES: CC1(C)c2cc(-c3ccc4ccc5cccc6ccc3c4c56)ccc2-c2ccc(-c3ccc4ccc5cccc6ccc3c4c56)cc21]
H12 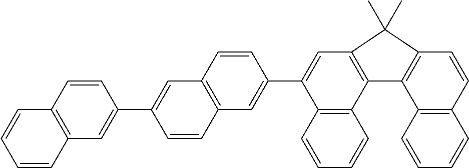 [SMILES: CC1(C)c2ccc3ccccc3c2-c2c1cc(-c1ccc3cc(-c4ccc5ccccc5c4)ccc3c1)c1ccccc21]
H13 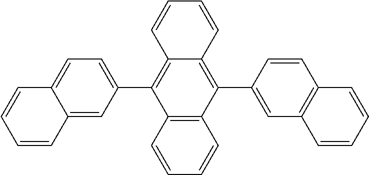 [SMILES: c1ccc2cc(-c3c4ccccc4c(-c4ccc5ccccc5c4)c4ccccc34)ccc2c1]
H14 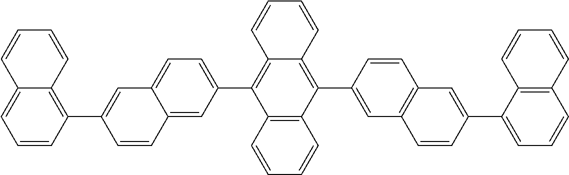 [SMILES: c1ccc2c(-c3ccc4cc(-c5c6ccccc6c(-c6ccc7cc(-c8cccc9ccccc89)ccc7c6)c6ccccc56)ccc4c3)cccc2c1]
H15 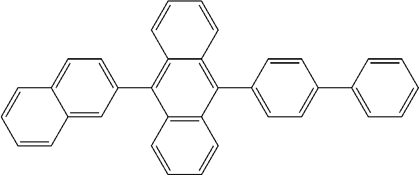 [SMILES: c1ccc(-c2ccc(-c3c4ccccc4c(-c4ccc5ccccc5c4)c4ccccc34)cc2)cc1]
H16 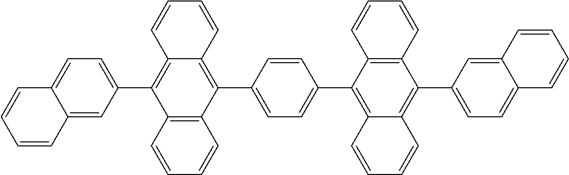 [SMILES: c1ccc2cc(-c3c4ccccc4c(-c4ccc(-c5c6ccccc6c(-c6ccc7ccccc7c6)c6ccccc56)cc4)c4ccccc34)ccc2c1]
H17 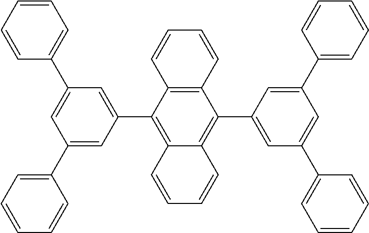 [SMILES: c1ccc(-c2cc(-c3ccccc3)cc(-c3c4ccccc4c(-c4cc(-c5ccccc5)cc(-c5ccccc5)c4)c4ccccc34)c2)cc1]
H18 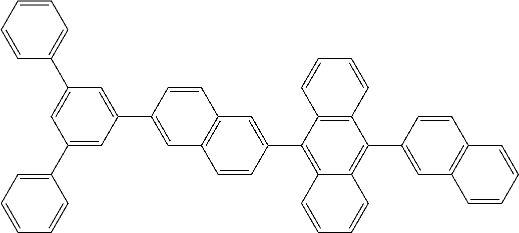 [SMILES: c1ccc(-c2cc(-c3ccccc3)cc(-c3ccc4cc(-c5c6ccccc6c(-c6ccc7ccccc7c6)c6ccccc56)ccc4c3)c2)cc1]
H19 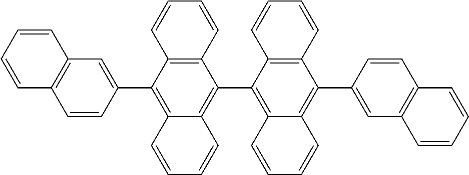 [SMILES: c1ccc2cc(-c3c4ccccc4c(-c4c5ccccc5c(-c5ccc6ccccc6c5)c5ccccc45)c4ccccc34)ccc2c1]
H20 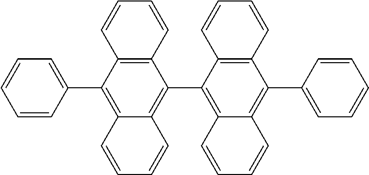 [SMILES: c1ccc(-c2c3ccccc3c(-c3c4ccccc4c(-c4ccccc4)c4ccccc34)c3ccccc23)cc1]
H21 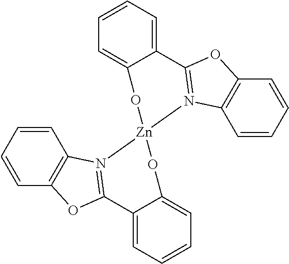
H22 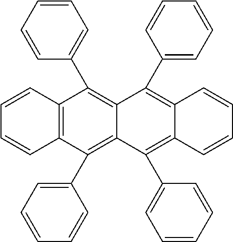 [SMILES: c1ccc(-c2c3ccccc3c(-c3ccccc3)c3c(-c4ccccc4)c4ccccc4c(-c4ccccc4)c23)cc1]
H23 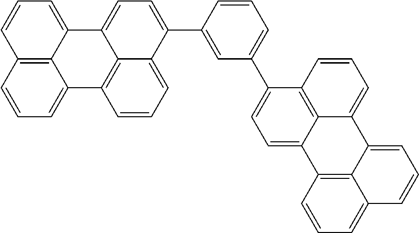 [SMILES: c1cc(-c2ccc3c4cccc5cccc(c6cccc2c63)c54)cc(-c2ccc3c4cccc5cccc(c6cccc2c63)c54)c1]
H24

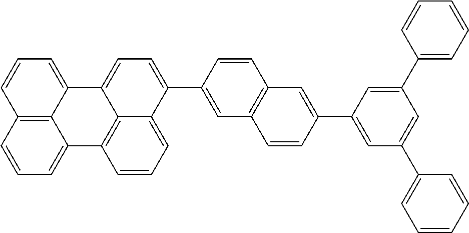 [SMILES: c1ccc(-c2cc(-c3ccccc3)cc(-c3ccc4cc(-c5ccc6c7cccc8cccc(c9cccc5c96)c87)ccc4c3)c2)cc1]

Furthermore, derivatives of the compounds shown in Table 4 also can be used as host materials. In addition, compounds other than the compounds shown in Table 4 can be used as host materials. Examples of such compounds include, but not limited to, fused compounds (e.g., fluorene derivatives, naphthalene derivatives, anthracene derivatives, pyrene derivatives, carbazole derivatives, quinoxaline derivatives, and quinoline derivatives), organic aluminum complexes such as tris(8-quinolinolate)aluminum, organic zinc complexes, triphenylamine derivatives, and polymer derivatives such as poly(fluorene) derivatives and poly(phenylene) derivatives.

The electron-injecting compound or the electron-transporting compound are selected by considering, for example, the balance with the hole mobility of the hole-injecting or transporting compound. Examples of the compound having electron-injecting or transporting ability include, but not limited to, oxadiazole derivatives, oxazole derivatives, pyrazine derivatives, triazole derivatives, triazine derivatives, quinoline derivatives, quinoxaline derivatives, phenanthroline derivatives, and organic aluminum complexes.

As the constituent material of the anode, a material having a higher work function is used. Examples thereof include simple metals such as gold, platinum, silver, copper, nickel, palladium, cobalt, selenium, vanadium, and tungsten and alloys of two or more thereof; and metal oxides such as tin oxide, zinc oxide, indium oxide, indium tin oxide (ITO), and indium zinc oxide. In addition, electrically conductive polymers such as polyaniline, polypyrrole, and polythiophene also can be used. These electrode materials may be used alone or in combination. The anode may be a monolayer or a multilayer.

On the contrary, as the constituent material of the cathode, a material having a lower work function is used, and examples thereof include alkali metals such as lithium; alkaline earth metals such as calcium; simple metals such as aluminum, titanium, manganese, silver, lead, and chromium; and alloys of combinations of these simple metals, such as magnesium-silver, aluminum-lithium, and aluminum-magnesium. In addition, metal oxides such as indium tin oxide (ITO) can be used. These electrode materials may be used alone or in combination. The cathode may be a monolayer or a multilayer.

In the organic light-emitting device according to the embodiment, a layer containing the organic compound according to the present invention and layers of other organic compounds are formed by the following methods. In general, thin films are formed by vacuum deposition, ionized vapor deposition, sputtering, plasma coating, or known coating (e.g., spin coating, dipping, a casting method, an LB method, or an ink-jetting method) of compounds dissolved in appropriate solvents. In the case of vacuum deposition, solution coating, or the like, crystallization hardly occurs, and the resulting layer is excellent in storage stability. In addition, in the coating, a film may be formed in a combination with an appropriate binder resin.

Examples of the binder resin include, but not limited to, polyvinyl carbazole resins, polycarbonate resins, polyester resins, ABS resins, acrylic resins, polyimide resins, phenol resins, epoxy resins, silicone resins, and urea resins. These binder resins may be used alone as a homopolymer or a copolymer or in a combination of two or more thereof. In addition, known additives such as a plasticizer, an antioxidant, and a UV absorber may be optionally contained in the films.

The organic light-emitting device according to the embodiment can be used as a structural member of a display apparatus or a lighting system. Other application includes exposure light sources of electrophotographic image forming apparatuses and backlights of liquid crystal display apparatuses.

Herein, the display apparatus includes the organic light-emitting device according to the embodiment in a display section. This display section includes pixels, and the pixels each include the organic light-emitting device according to the present invention. The display apparatus can be used as an image-displaying apparatus of, for example, a PC.

The display apparatus may be used in the display section of an image pickup apparatus such as a digital camera or a digital video camera. Herein, the image pickup apparatus includes the display section and an image pickup section having an image pickup optical system for imaging.

A display apparatus using the organic light-emitting device according to the embodiment will now be described with reference to the drawings.

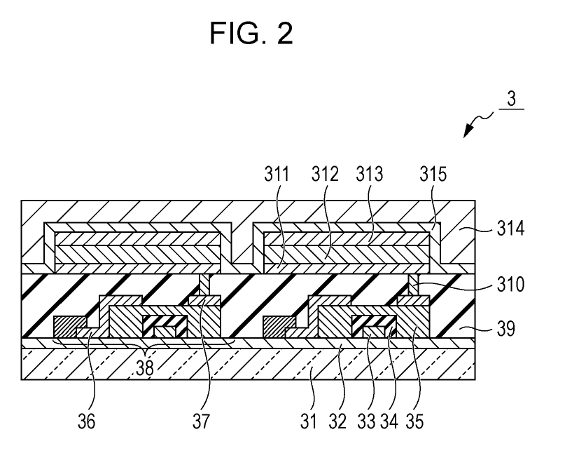

FIG. 2 is a schematic cross-sectional view illustrating an example of a display apparatus having organic light-emitting devices according to the embodiment and TFT devices as an example of switching elements electrically connected to the organic light-emitting devices. The details of the structure will be described below.

The display apparatus 3 shown in FIG. 2 includes a substrate 31 such as a glass substrate and a moisture-proof film 32 disposed on the substrate 31 for protecting the TFT devices or the organic compound layer. Reference numeral 33 denotes a gate electrode of a metal such as Cr, reference numeral 34 denotes a gate insulating film, and reference numeral 35 denotes a semiconductor layer.

The TFT device 38 includes a semiconductor layer 35, a drain electrode 36, and a source electrode 37. An insulating film 39 is disposed on the TFT device 38. The anode 311 of the organic light-emitting device and the source electrode 37 are connected via a contact hole (through hole) 310.

In FIG. 2 showing the display apparatus 3, the organic compound layer 312 having a monolayer or multilayer structure is shown as one layer. Furthermore, a first protective layer 314 and a second protective layer 315 are disposed on the cathode 313 in order to prevent deterioration of the organic light-emitting device.

In the organic light-emitting device according to the embodiment, the TFT device controls the luminance. By disposing the organic light-emitting devices in a plurality of planes, images can be displayed by the respective luminance. In addition, the luminance also can be controlled by producing an active matrix driver on a Si substrate, instead of the TFTs, and disposing the organic light-emitting devices thereon. This is selected depending on the definition. For example, in a definition for 1-inch QVGA, the organic light-emitting devices can be disposed on a Si substrate.

Stable display with a good image quality is possible even in display for a long time by driving the display apparatus using organic light-emitting devices according to the embodiment.

### EXAMPLES

The present invention will be described with reference to examples, but is not limited thereto.

### Example 1

### Synthesis of Example Compound 1

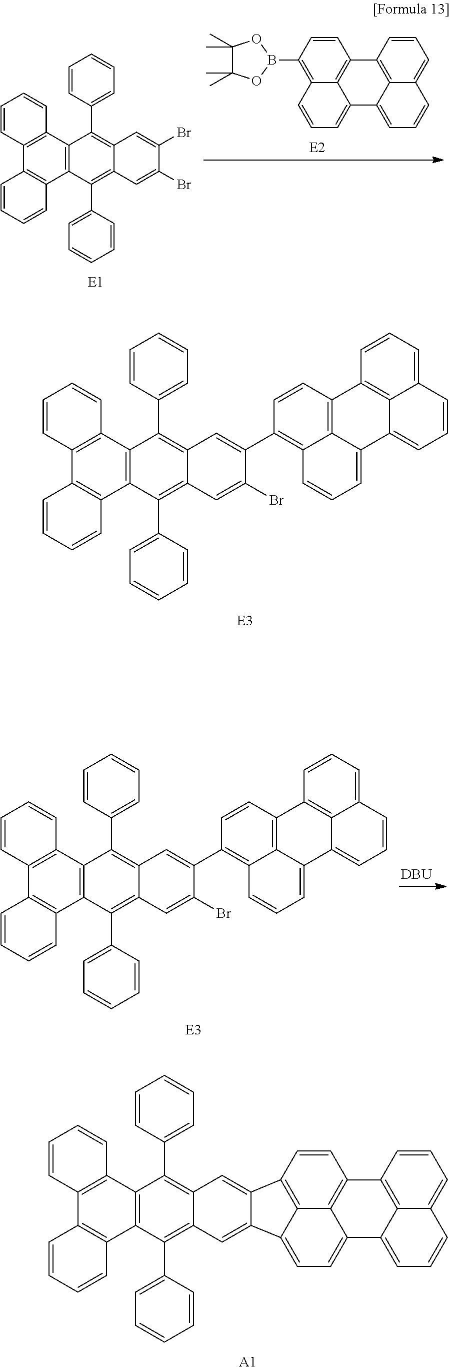

(1) Synthesis of Compound E3

The following reagents and solvents:

Compound E1: 606 mg (1 mmol),
Compound E2: 327 mg (1 mmol),
Pd(PPh₃)₄: 0.02 g toluene: 10 mL,
ethanol: 5 mL, and
an aqueous solution of 2 M sodium carbonate: 10 mL were charged in a 100-mL recovery flask. Compound E1 was synthesized based on the description in Japanese Patent Laid-Open No. 2010-254610.

Then, the reaction solution was stirred at 80° C. for 8 hr under a nitrogen gas flow. After completion of the reaction, the generated crystal was collected by filtration and was subjected to dispersion washing with water, ethanol, and heptane sequentially. Subsequently, the washed crystal was dissolved in toluene by heating. The resulting solution was purified by column chromatography (eluent: chloroform:heptane=1:3), followed by recrystallization from chloroform/methanol to obtain 583 mg (yield: 80%) of Compound E3 as a yellow crystal.

### (2) Synthesis of Example Compound A1

First, Compound E3 (200 mg, 0.3 mmol) was dissolved in 5 mL of DMA, and the following reagents:

Pd(dba)₂: 74 mg, and

P(Cy)₃: 12 mg

were added to the resulting solution.

Subsequently, the reaction solution was stirred at room temperature for 10 min, and DBU (120 mg, 0.8 mmol) was added thereto. The reaction solution was heated to 140° C. and was stirred at the same temperature (140° C.) for 1 min. Then, the reaction solution was heated to 160° C. and was stirred at the same temperature (160° C.) for 4 hr. After completion of the reaction, the generated red precipitate was collected by filtration to obtain a dark red solid. Then, this solid was dissolved in chlorobenzene by heating. The resulting solution was filtered in the hot state, followed by recrystallization from chlorobenzene/methanol twice to obtain 120 mg (yield: 68%) of Example Compound 1 as a dark red crystal. A hundred milligrams of the resulting Example Compound 1 was subjected to sublimation purification with a sublimation purification apparatus manufactured by Ulvac Kiko Inc. under the following conditions:

degree of vacuum: 7.0×10⁻¹ Pa,

argon gas flow rate: 10 mL/min, and

heating temperature (sublimation temperature): 410° C. to obtain 83 mg of purified Example Compound 1.

The purity of the resulting compound was measured by HPLC to confirm to be 99% or more.

The emission spectrum (photoluminescence) of a solution of Example Compound 1 in toluene (concentration: 1×10⁻⁵ mol/L) was measured using a fluorospectrophotometer, F-4500, manufactured by Hitachi, Ltd. The measurement was performed at an excitation wavelength of 500 nm. As a result, an emission spectrum having a maximum intensity at 554 nm was obtained.

Example Compound 1 has a low solubility in solvents, and, therefore, identification thereof by NMR is difficult. Accordingly, the compound was identified by measuring the molecular weight by a mass spectrometer, JMS-T100TD (DART-TOF-MASS), manufactured by JEOL Ltd. The result is shown below:

DART-TOF-MASS: M⁺=678.2.

### Example 2

### Synthesis of Example Compound A4

Example Compound A4 was synthesized as in Example 1 except that Compound E4 shown below was used instead of Compound E1 in Example 1(1).

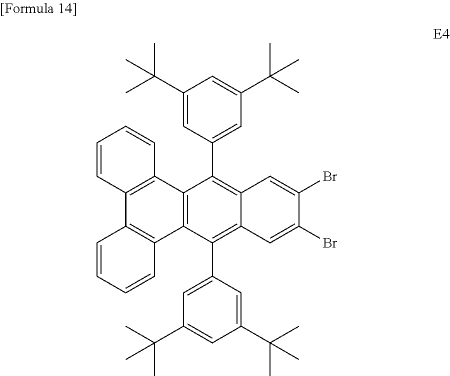 [SMILES: CC(C)(C)c1cc(-c2c3cc(Br)c(Br)cc3c(-c3cc(C(C)(C)C)cc(C(C)(C)C)c3)c3c4ccccc4c4ccccc4c23)cc(C(C)(C)C)c1]

The purity of the resulting compound was measured by HPLC to confirm to be 99.5% or more.

The emission spectrum of a solution of Example Compound A4 in toluene (concentration: 1×10⁻⁵ mol/L) was measured by the same method as in Example 1. As a result, an emission spectrum having a maximum intensity at 562 nm was obtained.

Furthermore, as in Example 1, the molecular weight of Example Compound A4 was measured to identify the compound.

The result is shown below:

DART-TOF-MASS: M⁺=903.2.

### Example 3

### Synthesis of Example Compound A5

Example Compound A5 was synthesized as in Example 1 except that Compound E5 shown below was used instead of Compound E1 in Example 1(1).

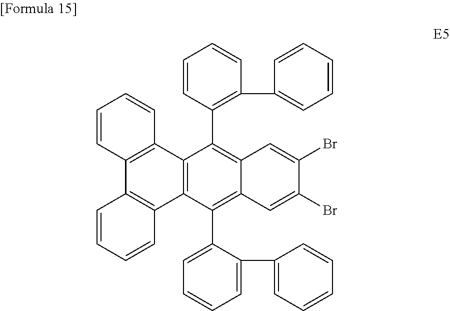 [SMILES: Brc1cc2c(-c3ccccc3-c3ccccc3)c3c4ccccc4c4ccccc4c3c(-c3ccccc3-c3ccccc3)c2cc1Br]

The purity of the resulting compound was measured by HPLC to confirm to be 99% or more.

The emission spectrum of a solution of Example Compound A5 in toluene (concentration: 1×10⁻⁵ mol/L) was measured by the same method as in Example 1. As a result, an emission spectrum having a maximum intensity at 555 nm was obtained.

Furthermore, as in Example 1, the molecular weight of Example Compound A5 was measured to identify the compound.

The result is shown below:

DART-TOF-MASS: M⁺=831.0.

### Example 4

### Synthesis of Example Compound 12

Example Compound 12 was synthesized as in Example 1 except that Compound E6 shown below was used instead of Compound E2 in Example 1(1).

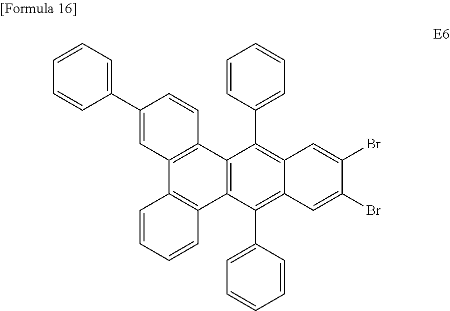 [SMILES: Brc1cc2c(-c3ccccc3)c3c4ccccc4c4cc(-c5ccccc5)ccc4c3c(-c3ccccc3)c2cc1Br]

The purity of the resulting compound was measured by HPLC to confirm to be 99% or more.

The emission spectrum of a solution of Example Compound 12 in toluene (concentration: 1×10⁻⁵ mol/L) was measured by the same method as in Example 1. As a result, an emission spectrum having a maximum intensity at 562 nm was obtained.

Furthermore, as in Example 1, the molecular weight of Example Compound 12 was measured to identify the compound. The result is shown below:

DART-TOF-MASS: M⁺=754.9.

### Example 5

### Synthesis of Example Compound A13

Example Compound A13 was synthesized as in Example 1 except that Compound E7 shown below was used instead of Compound E2 in Example 1(1).

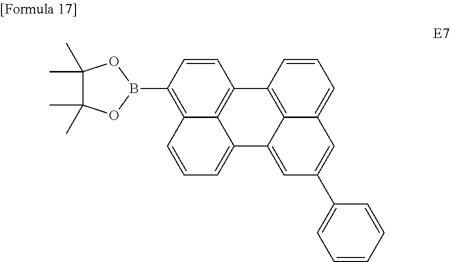 [SMILES: CC1(C)OB(c2ccc3c4cccc5cc(-c6ccccc6)cc(c6cccc2c36)c54)OC1(C)C]

The purity of the resulting compound was measured by HPLC to confirm to be 99% or more.

The emission spectrum of a solution of Example Compound A13 in toluene (concentration: 1×10⁻⁵ mol/L) was measured by the same method as in Example 1. As a result, an emission spectrum having a maximum intensity at 562 nm was obtained.

Furthermore, as in Example 1, the molecular weight of Example Compound A13 was measured to identify the compound. The result is shown below:

DART-TOF-MASS: M⁺=754.9.

### Example 6

In this Example, an organic light-emitting device in which an anode, a hole-transporting layer, a light-emitting layer, a hole/exciton-blocking layer, an electron-transporting layer, and a cathode were disposed on a substrate in this order was produced. A part of the materials used in this Example are shown below.

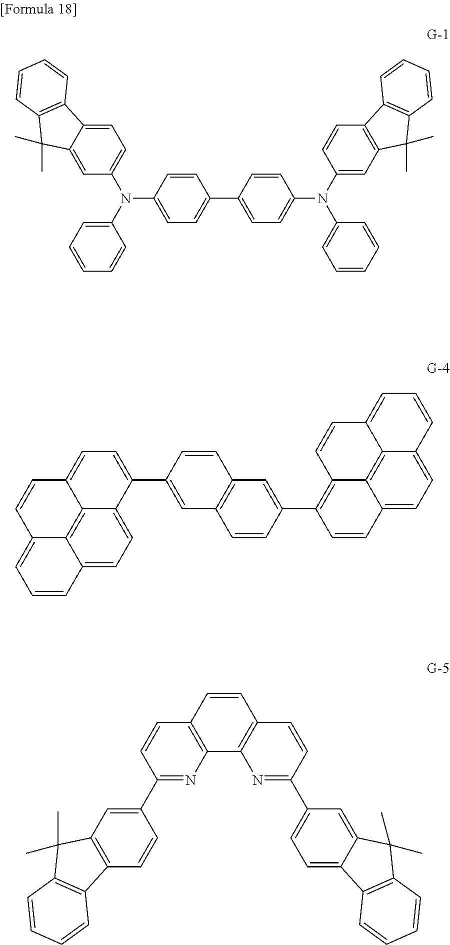

An ITO film having a thickness of 100 nm was formed on a glass substrate (substrate). The ITO film was patterned into a desired shape to form an ITO electrode (anode). The substrate thus provided with the ITO electrode was used as an ITO substrate in the following processes.

On this ITO substrate, organic compound layers and electrode layers shown in Table 5 were formed by resistance heating vacuum vapor deposition in a vacuum chamber of 1×10⁻⁵ Pa. On this occasion, the area where the electrodes (metal electrode layer, cathode) facing each other was adjusted to be 3 mm².

TABLE 5

| | | Thickness |
|---|---|---|
| | Material | (nm) |
| Hole-transporting layer | G-1 | 40 |
| Light-emitting layer | G-2 (host material) | 30 |
| | G-3 (assist material) | |
| | Example Compound A16 | |
| | (guest material) | |
| | (G-2:G-3:A1 = 60:39:1 | |
| | (weight ratio)) | |
| Hole/exciton-blocking layer | G-4 | 10 |
| Electron-transporting layer | G-5 | 30 |
| First metal electrode layer | LiF | 1 |
| Second metal electrode layer | Al | 100 |

In this Example, G-2 and G-3 correspond to H6 and H22 shown in Table 4, respectively.

The characteristics of the resulting device were measured and evaluated. Specifically, current-voltage characteristics were measured with a microammeter, 4140B, manufactured by Hewlett-Packard Company, and the luminance was measured with a luminance meter, BM7, manufactured by Topcon Corp. The results of the measurement are shown in Table 6.

### Examples 7 to 16

Organic light-emitting devices were produced as in Example 6 except that G-2, G-3, and the guest material were respectively changed to the compounds shown in Table 6. The characteristics of the resulting devices were measured and evaluated as in Example 6. The results of the measurement are shown in Table 6. In Table 6, H2, H4, H11, H18, H19, H20, H21, and H24 used as G-2 and H22, H23, and H24 used as G-3 are host materials shown in Table 4.

TABLE 6

| | Guest material | G-2 | G-3 | Luminous efficiency (cd/A) | Voltage (V) |
|---|---|---|---|---|---|
| Example 6 | A1 | H6 | H22 | 2.7 | 4.3 |
| Example 7 | A4 | H11 | H23 | 3.2 | 4.4 |
| Example 8 | A5 | H19 | H22 | 4.7 | 4.7 |
| Example 9 | A6 | H18 | H24 | 4.5 | 4.5 |
| Example 10 | A7 | H24 | H22 | 3.7 | 4.3 |
| Example 11 | A8 | H11 | H24 | 4.0 | 4.4 |
| Example 12 | A12 | H4 | H22 | 3.4 | 4.7 |
| Example 13 | A13 | H20 | H23 | 4.3 | 4.8 |
| Example 14 | A15 | H2 | H22 | 3.5 | 4.4 |
| Example 15 | A22 | H19 | H22 | 4.5 | 4.4 |
| Example 16 | B2 | H21 | H23 | 2.4 | 4.3 |

### Example 17

In this Example, an organic light-emitting device in which an anode, a hole-injecting layer, a hole-transporting layer, a light-emitting layer, an electron-transporting layer, an electron-injecting layer, and a cathode were disposed on a substrate in this order was produced. The organic light-emitting device produced in this Example has a resonance structure. A part of the materials used in this Example are shown below.

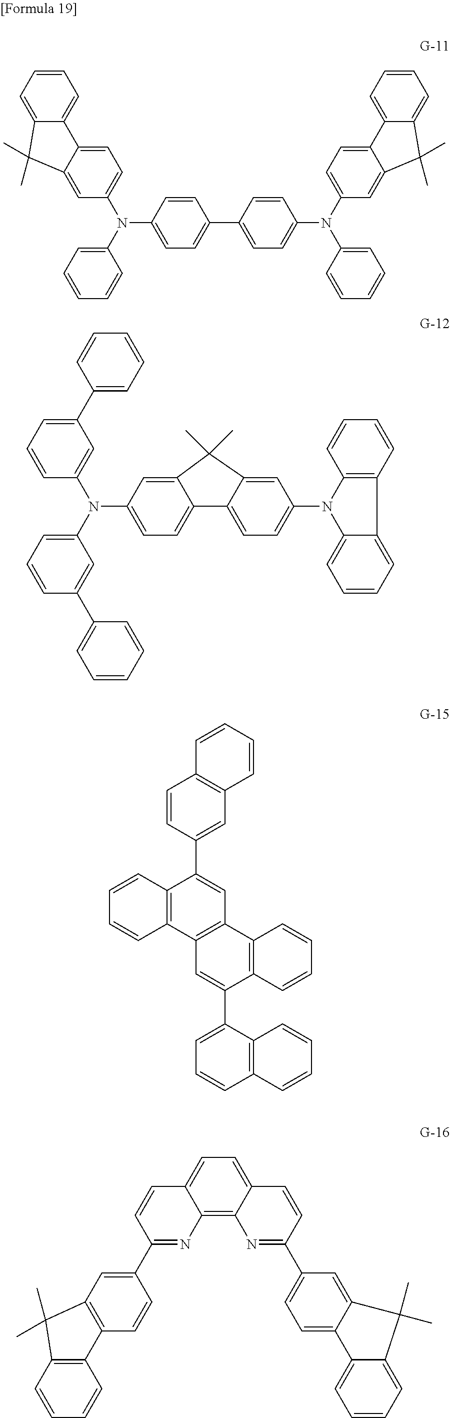

First, a film serving as a reflective anode having a thickness of 100 nm was formed on a glass substrate (support) by sputtering an aluminum alloy (AlNd). Then, a film serving as a transparent anode having a thickness of 80 nm was formed on the reflective anode by sputtering ITO. Furthermore, a device isolation acrylic film having a thickness of 1.5 μm was formed at the periphery of the anode, and an opening having a radius of 3 mm was formed by desired patterning formation. The substrate provided with the anodes was washed by ultrasonic cleaning with acetone and then isopropyl alcohol (IPA) and then washed by boiling in IPA, followed by drying. Furthermore, the surface of this substrate was washed with UV/ozone.

Then, organic compound layers shown in Table 7 were sequentially formed on the ITO substrate by resistance heating vacuum vapor deposition in a vacuum chamber of 1×10⁻⁵ Pa.

TABLE 7

| | | Thickness |
|---|---|---|
| | Material | (nm) |
| Hole-injecting layer | G-11 | 135 |
| Hole-transporting layer | G-12 | 10 |
| Light-emitting layer | G-13 (host material) | 35 |
| | G-14 (assist material) | |
| | Example Compound A16 | |
| | (guest material) | |
| | (G-13:G-14:A1= 70:29:1 | |
| | (weight ratio)) | |
| Electron-transporting layer | G-14 | 10 |
| Electron-injecting layer | G-15 | 70 |
| | Li | |
| | (G-15:Li = 80:20 (weight ratio)) | |

In this Example, G-13 and G-14 are respectively H11 and H24 shown in Table 4.

Then, a film serving as a cathode having thickness of 30 nm was formed on the electron-injecting layer by sputtering IZO. Lastly, sealing was performed in a nitrogen atmosphere. Thus, an organic light-emitting device was produced.

The characteristics of the resulting device were measured and evaluated. Specifically, current-voltage characteristics were measured with a microammeter, 4140B, manufactured by Hewlett-Packard Company, and the luminance was measured with a luminance meter, BM7, manufactured by Topcon Corp. The results of the measurement are shown in Table 8.

### Examples 18 to 21

Organic light-emitting devices were produced as in Example 17 except that G-13, G-14, and the guest material were respectively changed to the compounds shown in Table 8. The characteristics of the resulting devices were measured and evaluated as in Example 17. The results of the measurement are shown in Table 8. In Table 8, H6, H19, H23, and H24 used as G-13 and H22 and H23 used as G-14 are host materials shown in Table 4.

TABLE 8

| | Guest material | G-13 | G-14 | Luminous efficiency (cd/A) | Voltage (V) |
|---|---|---|---|---|---|
| Example 17 | A1 | H11 | H24 | 6.5 | 4.7 |
| Example 18 | A4 | H19 | H22 | 6.8 | 4.8 |
| Example 19 | A14 | H23 | H22 | 7.5 | 4.4 |
| Example 20 | A17 | H24 | H22 | 7.3 | 4.6 |
| Example 21 | A24 | H6 | H23 | 7.0 | 4.5 |

### Example 22

In this Example, an organic light-emitting device in which an anode, a hole-transporting layer, a first light-emitting layer, a second light-emitting layer, a hole/exciton blocking layer, an electron-transporting layer, and a cathode were disposed on a substrate in this order was produced. The organic light-emitting device in this Example has a plurality of light-emitting layers, and the guest materials contained in the light-emitting layers emit light separately or simultaneously. A part of the materials used in this Example are shown below.

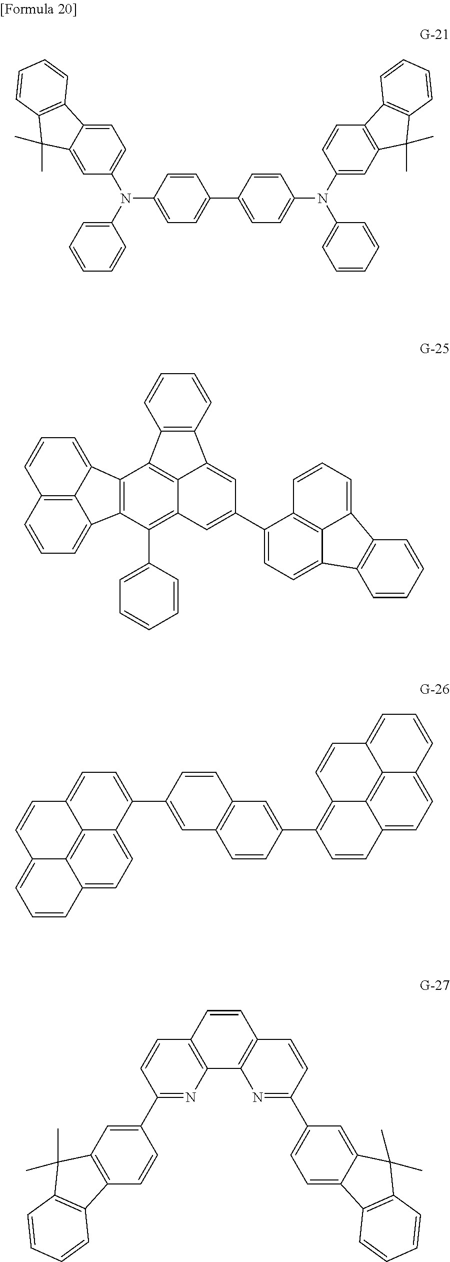

First, a film serving as an ITO electrode having a thickness of 100 nm was formed on a glass substrate by sputtering ITO. The substrate provided with the ITO electrode was used as an ITO substrate in the following processes.

On this ITO substrate, organic compound layers and electrode layers shown in Table 9 were successively formed by resistance heating vacuum vapor deposition in a vacuum chamber of 1×10⁻⁵ Pa. On this occasion, the area where the electrodes (metal electrode layer, cathode) facing each other was adjusted to be 3 mm².

TABLE 9

| | | Thickness |
|---|---|---|
| | Material | (nm) |
| Hole-transporting layer | G-21 | 40 |
| First light-emitting layer | G-22 (first host material) | 30 |
| | G-23 (first assist material) | |
| | Example Compound A2 | |
| | (first guest material) | |
| | (G-22:G-23:A1 = 60:39:1 | |
| | (weight ratio)) | |
| Second light-emitting layer | G-24 (second host material) | 10 |
| | G-25 (second guest material) | |
| | (G-24:G-25 = 98:2 (weight ratio)) | |
| Hole/exciton-blocking layer | G-26 | 10 |
| Electron-transporting layer | G-27 | 30 |
| First metal electrode layer | LiF | 1 |
| Second metal electrode layer | Al | 100 |

In this Example, G-22, G-23, and G-24 are respectively H11, H22, and H17 shown in Table 4.

The characteristics of the resulting device were measured and evaluated. Specifically, current-voltage characteristics were measured with a microammeter, 4140B, manufactured by Hewlett-Packard Company, and the luminance was measured with a luminance meter, BM7, manufactured by Topcon Corp. The results of the measurement are shown in Table 10.

### Examples 23 and 24

Organic light-emitting devices were produced as in Example 22 except that G-22, G-23, G-24, and the guest material were respectively changed to the compounds shown in Table 10. The characteristics of the resulting devices were measured and evaluated as in Example 22. The results of the measurement are shown in Table 10. In Table 10, H18 and H23 used as G-22, H22 and H23 used as G-23, and H17 and H18 used as G-23 are host and assist materials shown in Table 4.

TABLE 10

| | Guest material | G-22 | G-23 | Luminous efficiency (cd/A) | Voltage (V) |
|---|---|---|---|---|---|
| Example 22 | A1 | H11 | H22 | 7.5 | 4.4 |
| Example 23 | A4 | H18 | H22 | 7.3 | 4.6 |
| Example 24 | A15 | H23 | H23 | 7.0 | 4.5 |

The organic compounds according to the present invention are compounds emitting yellow light and having high quantum yields. Accordingly, organic light-emitting devices having good light-emitting characteristics can be provided by using the organic compounds according to the present invention as constituent materials of the organic light-emitting devices.

While the present invention has been described with reference to exemplary embodiments, it is to be understood that the invention is not limited to the disclosed exemplary embodiment. The scope of the following claims is to be accorded the broadest interpretation so as to encompass all such modifications and equivalent structures and functions.

This application claims the benefit of Japanese Patent Application No. 2011-018366, filed Jan. 31, 2011, which is hereby incorporated by reference herein in its entirety.

### REFERENCE SIGNS LIST

311 anode
12 organic compound layer
313 cathode
38 TFT device

1. An organic compound represented by the following Formula (1): 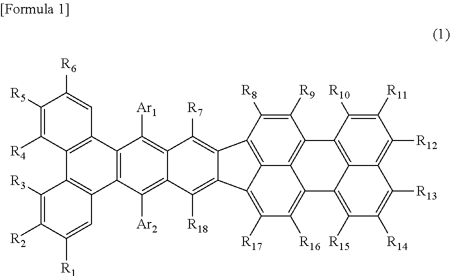
in Formula (1), R₁ to R₁₈ each independently represent a substituent selected from hydrogen atoms, halogen atoms, substituted or unsubstituted alkyl groups, substituted or unsubstituted alkoxy groups, substituted or unsubstituted amino groups, substituted or unsubstituted aryl groups, and substituted or unsubstituted heterocyclic groups; and Ar₁ and Ar₂ each represent a substituted or unsubstituted aryl group.

2. The organic compound according to claim 1, wherein
R₁ to R₁₈ each independently represent a hydrogen atom, a substituted or unsubstituted alkyl group, or a substituted or unsubstituted aryl group.

3. The organic compound according to claim 1, wherein
R₁, R₂, R₅, R₆, and R₁₁ to R₁₄ each independently represent a hydrogen atom or a substituted or unsubstituted aryl group;
R₃, R₄, R₇ to R₁₀, and R₁₅ to R₁₈ each represent a hydrogen atom; and
Ar₁ and Ar₂ each represent an aryl group.

4. An organic light-emitting device comprising:
an anode and a cathode; and
an organic compound layer disposed between the anode and the cathode, wherein
the organic compound layer includes at least one layer containing the organic compound according to claim 1.

5. The organic light-emitting device according to claim 4, wherein the organic compound is contained in a light-emitting layer.

6. The organic light-emitting device according to claim 4, the device emitting yellow light.

7. An image display apparatus comprising:
a plurality of pixels each having the organic light-emitting device according to claim 4 and a TFT device controlling the luminance of the organic light-emitting device.

8. An image pickup apparatus comprising:
a display section and an image pickup section, wherein
the display section includes a plurality of pixels each having the organic light-emitting device according to claim 4 and a TFT device controlling the luminance of the organic light-emitting device; and
the image pickup section includes an image pickup optical system.

9. A lighting system comprising the organic light-emitting device according to claim 4.

10. An exposure light source of electrophotographic image forming apparatus,
the exposure light source comprising the organic light-emitting device according to claim 4.

11. An apparatus comprising the organic light-emitting device according to claim 4.
